(19) United States
(12) Patent Application Publication
(10) Pub. No.: US 2026/0020416 A1
(43) Pub. Date: Jan. 15, 2026

(54) DISPLAY DEVICE AND METHOD OF MANUFACTURING THE SAME, AND ELECTRONIC DEVICE FOR PROVIDING IMAGE

(71) Applicant: Samsung Display Co., LTD., Yongin-si (KR)

(72) Inventor: Young Chul SIM, Yongin-si (KR)

(73) Assignee: Samsung Display Co., LTD., Yongin-si (KR)

(21) Appl. No.: 19/191,624

(22) Filed: Apr. 28, 2025

(30) Foreign Application Priority Data
Jul. 9, 2024 (KR) 10-2024-0090104

(51) Int. Cl. H10H 29/856; H01L 25/075; H10H 29/01; H10H 29/49; H10K 59/12; H10K 59/131; H10K 59/80

(52) U.S. Cl. CPC H10H 29/856; H01L 25/0753; H10H 29/012; H10H 29/032; H10H 29/0363; H10H 29/49; H10K 59/1201; H10K 59/1315; H10K 59/878

(57) ABSTRACT

A display device includes a lower substrate, light emitting elements disposed on the lower substrate, a passivation layer covering side surfaces of the light emitting elements, an insulating layer disposed on the passivation layer and including a groove surrounding the light emitting elements, and a reflective film disposed on the groove and surrounding the side surfaces of the light emitting elements.

### CROSS-REFERENCE TO RELATED APPLICATION(S)

This application claims priority to and benefits of Korean Patent Application No. 10-2024-0090104 under 35 U.S.C. § 119, filed on Jul. 9, 2024, in the Korean Intellectual Property Office, the entire contents of which are incorporated herein by reference.

### BACKGROUND

### 1. Technical Field

The disclosure relates to a display device and a method of manufacturing the same, and an electronic device for providing an image.

### 2. Description of the Related Art

As the information society develops, demands for display devices for displaying images are increasing in various forms. Accordingly, various types of display devices including light emitting display devices are being developed. A light emitting display device may include pixels including light emitting elements.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device which can improve the light efficiency of pixels and a method of manufacturing the display device, and an electronic device for providing an image.

However, aspects of the disclosure are not restricted to the ones set forth herein. The above and other aspects of the disclosure will become more apparent to one of ordinary skill in the art to which the disclosure pertains by referencing the detailed description of the disclosure given below.

According to an aspect of the disclosure, there is provided a display device that may include a lower substrate; light emitting elements disposed on the lower substrate; a passivation layer covering side surfaces of the light emitting elements; an insulating layer disposed on the passivation layer and including a groove surrounding the light emitting elements; and a reflective film disposed on the groove and surrounding the side surfaces of the light emitting elements.

In an embodiment, the reflective film may have a mesh shape including openings exposing the light emitting elements in plan view.

In an embodiment, the reflective film and the light emitting elements may not overlap each other in plan view.

In an embodiment, the reflective film may include a surface having a textured pattern and may have a surface roughness according to the textured pattern.

In an embodiment, a depth of the groove may be equal or greater than a thickness of the light emitting elements, and a bottom surface of the reflective film may be disposed at the same height as or below the light emitting elements.

In an embodiment, the reflective film may completely surround the side surfaces of each of the light emitting elements.

In an embodiment, the reflective film may include a metal or distributed Bragg reflectors.

In an embodiment, the display device may further include bonding electrodes disposed on the lower substrate, and the light emitting elements may be disposed on the bonding electrodes.

In an embodiment, each of the bonding electrodes may include a bonding layer and a reflective layer disposed on the bonding layer.

In an embodiment, the reflective layer of each of the bonding electrodes may completely cover a lower surface of each of the light emitting elements.

In an embodiment, the display device may further include a common electrode disposed on the insulating layer and electrically connected to the light emitting elements.

In an embodiment, the passivation layer and the insulating layer may include openings exposing upper surfaces of the light emitting elements, and the common electrode may be electrically connected to the light emitting elements in the openings.

In an embodiment, the display device may further include a power line disposed on the reflective film and filling the groove, and the common electrode may be disposed on the power line.

In an embodiment, the power line may have a mesh shape including openings exposing the light emitting elements in plan view.

In an embodiment, the reflective film may include a conductive material, and the power line may be directly disposed on the reflective film.

In an embodiment, the display device may further include a cover layer disposed on the common electrode, and lenses disposed on the cover layer and overlapping the light emitting elements.

In an embodiment, the lower substrate may include pixel electrodes electrically connected to the light emitting elements and pixel circuits electrically connected to the pixel electrodes.

According to an aspect of the disclosure, there is provided a method of manufacturing a display device, the method may include, preparing a lower substrate including pixel circuits; forming light emitting elements, electrically connected to the pixel circuits, on the lower substrate; forming a passivation layer, covering the light emitting elements, on the lower substrate; forming an insulating layer, including a groove surrounding the light emitting elements, on the passivation layer; forming a reflective film, surrounding side surfaces of the light emitting elements, on the groove; and forming a common electrode, electrically connected to the light emitting elements, on the insulating layer.

In an embodiment, the forming of the insulating layer may include forming the insulating layer on the passivation layer to a height greater than a height of the light emitting elements such that the insulating layer completely covers the light emitting elements, and forming the groove in the insulating layer by etching the insulating layer in a portion not overlapping the light emitting elements.

In an embodiment, the method may further include forming a textured pattern on a surface of the reflective film after the reflective film is formed.

According to an aspect of the disclosure, there is provided an electronic device for providing an image, that may include a display device, the display device including a lower substrate; light emitting elements disposed on the lower substrate; a passivation layer covering side surfaces of the light emitting elements; an insulating layer disposed on the passivation layer and including a groove surrounding the light emitting elements, and a reflective film disposed on the groove and surrounding the side surfaces of the light emitting elements.

The reflective film may have a mesh shape comprising openings exposing the light emitting elements in plan view.

The reflective film and the light emitting elements may not overlap each other in plan view.

The reflective film may comprise a surface having a textured pattern and has a surface roughness according to the textured pattern.

A depth of the groove may be equal or greater than a thickness of the light emitting elements, and a bottom surface of the reflective film is disposed at a same height as or below the light emitting elements.

The reflective film may completely surround the side surfaces of each of the light emitting elements.

The electronic device may be at least one of an organic light-emitting display apparatus, an inorganic light-emitting display apparatus, a quantum dot light-emitting display apparatus, display screens of portable electronic apparatus, such as mobile phones, smartphones, tablet personal computers (PCs), mobile communication terminals, electronic notebooks, electronic books, portable multimedia players (PMPs), navigation devices, and ultra mobile PCs (UMPCs), display screens of televisions, notebooks, monitors, advertisement panels, Internet of things (IoT) devices, a portable communication device a smartphone, a computer device, a portable multimedia device, a portable medical device, a camera, a wearable device, and a home appliance.

According to a display device and a method of manufacturing the same according to embodiments, the light efficiency of light emitting elements and pixels including the light emitting elements can be increased. Light leakage or light interference between the pixels can be prevented, and the electrical stability of the light emitting elements can be secured.

However, effects according to the embodiments of the disclosure are not limited to those described above and various other effects are incorporated herein.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic perspective view of a display device according to an embodiment;

FIG. 2 is a schematic plan view of a display area according to an embodiment;

FIG. 3 is a schematic cross-sectional view of a display panel according to an embodiment;

FIG. 4 is a schematic cross-sectional view of a display panel according to an embodiment;

FIGS. 5 through 7 are schematic perspective views illustrating a method of manufacturing a display device according to an embodiment;

FIGS. 8 through 20 are schematic cross-sectional views illustrating the method of manufacturing the display device according to the embodiment;

FIG. 21 is an example view of a smart watch including a display device according to an embodiment;

FIGS. 22 and 23 are example views of a virtual reality (VR) device including display devices according to an embodiment;

FIG. 24 is an example view of a VR device including a display device according to an embodiment;

FIG. 25 is an example view illustrating a vehicle instrument cluster and center fascia including display devices according to an embodiment; and

FIG. 26 is an example view of a transparent display device including a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when an element or a layer is referred to as being “on” another element or layer, it can be directly on the other element or layer, or intervening layers may also be present. The same reference numbers indicate the same components throughout the specification.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Features of each of various embodiments of the disclosure may be partially or entirely combined with each other and, and respective embodiments may be implemented independently of each other or may be implemented together.

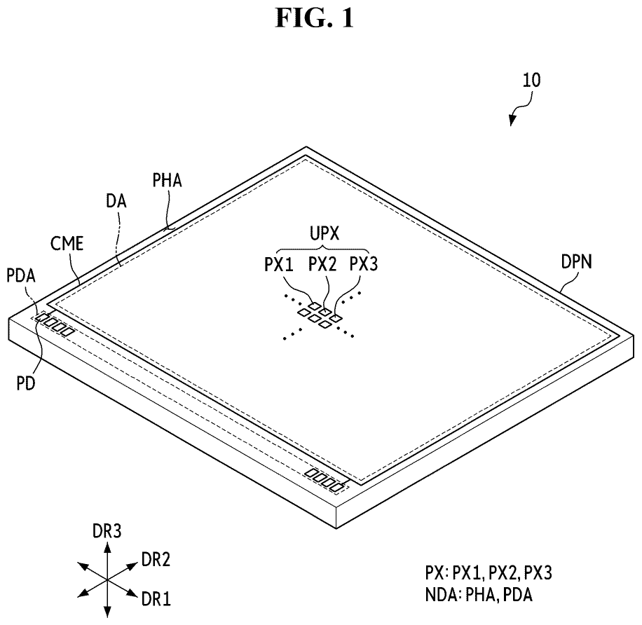

FIG. 1 is a schematic perspective view of a display device 10 according to an embodiment.

Referring to FIG. 1, the display device 10 is a device for displaying moving images or still images and may be used as a display screen in various products (for example, electronic devices). For example, the display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various electronic devices such as televisions, notebook computers, monitors, billboards and Internet of things (IoT) devices. The display device 10 may be applied to virtual reality (VR) devices or augmented reality (AR) devices. For example, the display device 10 may be included in at least one of the electronic devices described above or may be included in other types of electronic devices. The electronic device may be at least one of an organic light-emitting display apparatus, an inorganic light-emitting display apparatus, a quantum dot light-emitting display apparatus, advertisement panels, a portable communication device a smartphone, a computer device, a portable multimedia device, a portable medical device, a camera, a wearable device, and a home appliance.

The display device 10 according to the embodiment may include a display panel DPN including a display area DA and a non-display area NDA.

The display panel DPN may have a quadrangular planar shape having long sides in a first direction DR1 and short sides in a second direction DR2. In FIG. 1, the first direction DR1 may indicate a horizontal direction of the display panel DPN, and the second direction DR2 may indicate a vertical direction of the display panel DPN. A third direction DR3 may indicate a thickness direction or a height direction of the display panel DPN. However, the planar shape of the display panel DPN is not limited thereto, and the display panel DPN may also have other shapes. For example, the display panel DPN may have a polygonal shape other than the quadrangular shape, a circular shape, an oval shape, or an irregular shape in plan view.

The display area DA may be an area where an image is displayed, and the non-display area NDA may be an area where an image is not displayed. In an embodiment, the planar shape of the display area DA may follow the planar shape of the display panel DPN. FIG. 1 illustrates an embodiment in which the planar shape of the display area DA is a quadrangle. The display area DA may be disposed at a center of the display panel DPN. The non-display area NDA may be disposed around the display area DA. For example, the non-display area NDA may be disposed at edges of the display panel DPN to surround (or to be adjacent to) the display area DA.

The display panel DPN may include pixels PX arranged (or disposed) in the display area DA. For example, the display panel DPN may include first pixels PX1 emitting light of a first color, second pixels PX2 emitting light of a second color, and third pixels PX3 emitting light of a third color. In an embodiment, the first color may be red, the second color may be green, and the third color may be blue, but embodiments are not limited thereto. At least one first pixel PX1, at least one second pixel PX2, and at least one third pixel PX3 adjacent to each other may form a unit pixel UPX that can emit light of various colors. For example, a first pixel PX1, a second pixel PX2, and a third pixel PX3 sequentially or continuously disposed along the first direction DR1 in the display area DA may form one unit pixel UPX. The number, type, and/or arrangement structure of pixels PX that form a unit pixel UPX may vary according to embodiments.

The pixels PX may have a quadrangular planar shape such as a rectangle or a rhombus, but embodiments are not limited thereto. For example, the pixels PX may also have other polygonal shapes (for example, a hexagonal shape or a rhombic shape), a circular shape, an oval shape, or other shapes in plan view.

The pixels PX may be arranged in the display area DA in a matrix form, a stripe form, or any other form. Sizes of the pixels PX may be the same or different from each other.

In an embodiment, the display device 10 may be a light emitting display device including light emitting elements. For example, each of the pixels PX of the display device 10 may include at least one light emitting element.

The non-display area NDA may include a pad area PDA and a peripheral area PHA. In an embodiment, the non-display area NDA may further include a common voltage supply area, etc. disposed around the display area DA. In the non-display area NDA, lines (or portions of the lines) connected to the pixels PX and pads PD may be disposed. In the description of embodiments, the term “connection” may include the meaning of electrical connection and/or physical connection.

The pads PD may be disposed in the pad area PDA. The pads PD may be connected to an external circuit board. For example, the pads PD may be electrically connected to circuit pads on the circuit board through conductive connection members such as wires. Driving signals and driving voltages for driving the pixels PX may be supplied from the circuit board to the display device 10 (or the display panel DPN) through the pads PD.

The peripheral area PHA may be an area excluding the pad area PDA from the non-display area NDA. The peripheral area PHA may surround the display area DA.

In an embodiment, the display device 10 may include a common electrode CME disposed in the entire display area DA. The common electrode CME may be electrically connected to at least one pad PD disposed in the pad area PDA and may receive a second driving voltage for driving light emitting elements through the pad PD. In an embodiment, the second driving voltage may be a common voltage such as a low-potential pixel voltage or a cathode voltage. For example, the common electrode CME may be electrically connected to pads PD disposed at both ends of the pad area PDA and may receive a common voltage from the circuit board through the pads PD. The shape, structure, and/or position of the common electrode CME are not limited to the embodiment of FIG. 1 and may vary according to embodiments.

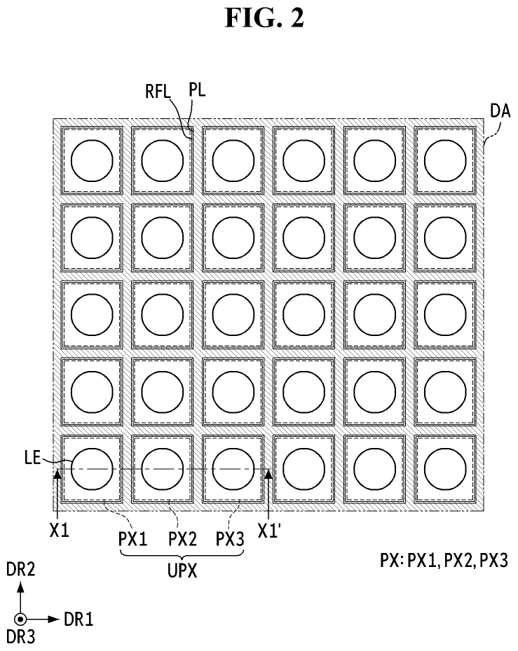

In an embodiment, the display device 10 may further include a power line (for example, a power line PL of FIG. 2) disposed between the pixels PX and electrically connected to the common electrode CME. Accordingly, the common voltage can be supplied more smoothly to the pixels PX.

The pixels PX may receive the common voltage through the common electrode CME. The pixels PX may be connected to other pads PD of the pad area PDA and a driver circuit (not illustrated). For example, the pixels PX may include circuit elements formed on a semiconductor circuit board (for example, circuit elements that constitute a pixel circuit of each pixel PX) and may be electrically connected to other pads PD of the pad area PDA and/or a driver circuit through lines connected to the circuit elements. The shape or position of each line or electrode (for example, the common electrode CME) for supplying each driving signal or each driving voltage to the pixels PX may vary according to embodiments. The driver circuit may be disposed in the display panel DPN or may be provided outside of the display panel DPN and electrically connected to the pads PD disposed in the pad area PDA.

The pixels PX may receive driving signals (for example, a scan signal or a control signal and a data signal) and a first driving voltage from the other pads PD and/or the driver circuit. In an embodiment, the first driving voltage may be a pixel voltage such as a high-potential pixel voltage or an anode voltage. The pixels PX may emit light in response to the driving signals and the driving voltages (for example, the first driving voltage and the second driving voltage).

FIG. 2 is a schematic plan view of a display area DA according to an embodiment. For example, FIG. 2 schematically illustrates a portion of the display area DA according to the embodiment of FIG. 1.

Referring to FIGS. 1 and 2, each pixel PX may include a light emitting element LE. Although FIG. 2 discloses an embodiment in which each pixel PX may include a single light emitting element LE, embodiments are not limited thereto. For example, at least one of the first pixels PX1, the second pixels PX2, and the third pixels PX3 may also include two or more light emitting elements LE.

The light emitting elements LE may have a circular shape, a quadrangular shape, a polygonal shape other than the quadrangular shape, or other shapes in plan view. For example, the shape of the light emitting elements LE may vary according to embodiments.

In an embodiment, the light emitting elements LE may be micro-light emitting diodes (micro-LEDs) having a small size of micrometers (μm). For example, each of the light emitting elements LE may be a micro-LED whose length in the first direction DR1 (for example, horizontal length), length in the second direction DR2 (for example, vertical length), and length in the third direction DR3 (for example, thickness or height) are each several micrometers to hundreds of micrometers. In an embodiment, the length in the first direction DR1, the length in the second direction DR2, and the length in the third direction DR3 of each of the light emitting elements LE may each be, but are not limited to, 100 μm or less.

In an embodiment, the first pixels PX1, the second pixels PX2, and the third pixels PX3 may include light emitting elements LE that emit light of the first color, light of the second color, and light of the third color, respectively. In an embodiment, the first pixels PX1, the second pixels PX2, and the third pixels PX3 may include light emitting elements LE that emit light of the same color, and light conversion patterns (for example, wavelength conversion patterns including quantum dots) and/or color filters may be disposed in emission areas of the first pixels PX1, the second pixels PX2, and/or the third pixels PX3 to convert the color or wavelength of light emitted from the light emitting elements LE disposed in the pixels PX, respectively.

In an embodiment, the pixels PX may be arranged in the display area DA in a matrix form, a stripe form, or any other form. The sizes of the pixels PX (or the emission areas of the pixels PX) may be substantially the same or different from each other.

In an embodiment, the pixels PX may have a quadrangular planar shape such as a rectangle or a rhombus, but embodiments are not limited thereto. For example, the pixels PX may also have other polygonal shapes (for example, a hexagonal shape or a rhombic shape), a circular shape, an oval shape, or other shapes in plan view.

The display device 10 may include a reflective film RFL disposed between the light emitting elements LE. For example, the reflective film RFL may have a mesh shape when viewed in a plane (for example, a plane defined by the first direction DR1 and the second direction DR2) and may surround each of the light emitting elements LE. The reflective film RFL may be disposed between the pixels PX so as not to overlap the pixels PX. By way of example, a portion of the reflective film RFL may overlap an edge portion of each pixel PX.

In an embodiment, the reflective film RFL may not overlap the light emitting elements LE in plan view. For example, the reflective film RFL may have an opening formed on each of the light emitting elements LE to have an area equal to or greater than the area of each of the light emitting elements LE and may not cover upper surfaces of the light emitting elements LE. Accordingly, an emission angle of light emitted from each of the light emitting elements LE can be sufficiently secured or widened.

In an embodiment, the display device 10 may further include a power line PL disposed between the light emitting elements LE. For example, the power line PL may have a mesh shape in plan view and may overlap the reflective film RFL. In an embodiment, the power line PL may be electrically connected to the common electrode CME. The power line PL disposed between the light emitting elements LE can reduce or minimize a voltage drop of the common voltage applied to the common electrode CME and can improve the image quality and power consumption of the display device 10.

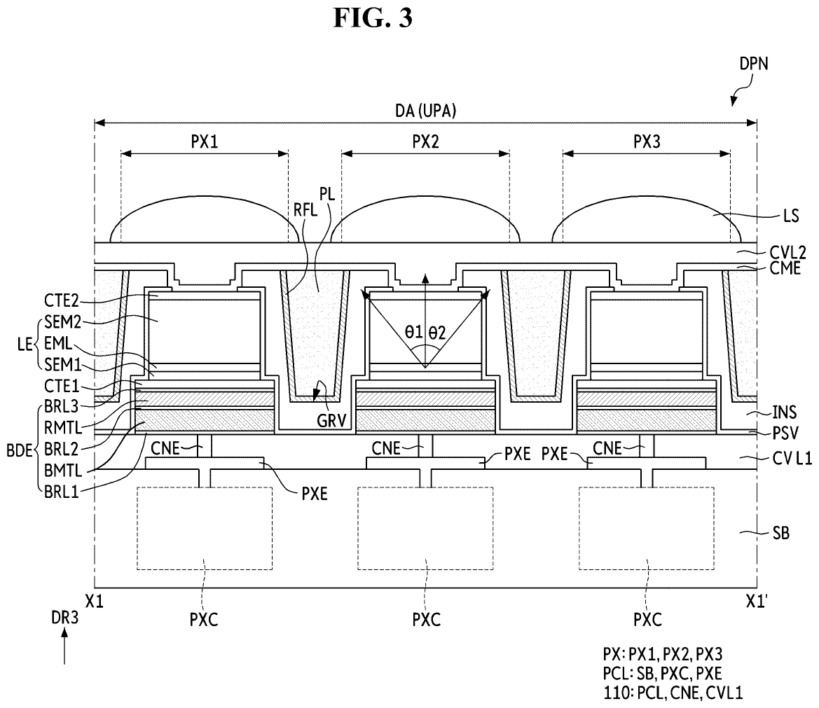

FIG. 3 is a schematic cross-sectional view of a display panel DPN according to an embodiment. For example, FIG. 3 illustrates an embodiment of a schematic cross section of the display panel DPN corresponding to line X1-X1′ of FIG. 2 and illustrates a schematic cross section of a first pixel PX1, a second pixel PX2, and a third pixel PX3 located (or disposed) in a unit pixel area UPA of the display area DA.

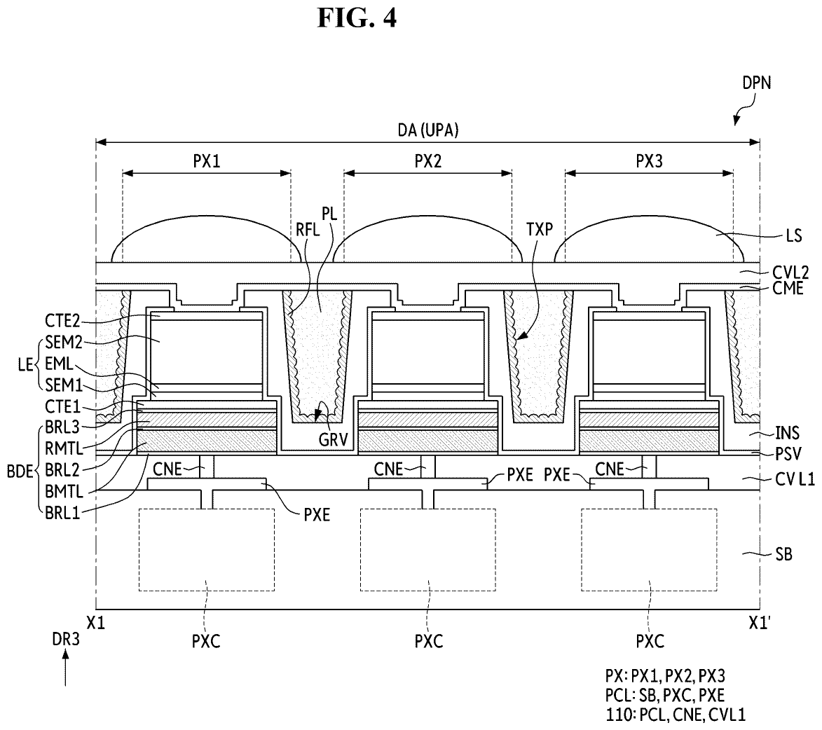

FIG. 4 is a schematic cross-sectional view of a display panel DPN according to an embodiment. FIG. 4 illustrates an embodiment that may be different from the embodiment of FIG. 3 in the reflective film RFL.

FIGS. 3 and 4 illustrate an embodiment in which the display device 10 may include a display panel DPN having a light emitting diode on silicon (LEDOS) structure in which light emitting diodes are disposed as light emitting elements LE on a semiconductor circuit board PCL formed by a semiconductor process using a silicon wafer. However, the structure or type of device to which embodiments can be applied is not limited thereto. For example, the embodiments can also be applied to display devices of other types and/or structures or applied to devices of other types and/or structures, such as lighting devices.

Referring to FIGS. 1 through 4, the display panel DPN may include the semiconductor circuit board PCL (or a thin-film transistor substrate), connection electrodes CNE and a first cover layer CVL1 disposed on the semiconductor circuit board PCL, bonding electrodes BDE disposed on the connection electrodes CNE and the first cover layer CVL1, and light emitting elements LE disposed on the bonding electrodes BDE. In an embodiment, the display panel DPN may further include at least one of contact electrodes CTE1 and CTE2 disposed on at least one surface or a surface of each light emitting element LE, a passivation layer PSV covering side surfaces of the light emitting elements LE, an insulating layer INS, the reflective film RFL and the power line PL disposed around the light emitting elements LE, and the common electrode CME and a second cover layer CVL2 disposed on the light emitting elements LE. In an embodiment, the display panel DPN may further include an optical structure, for example, lenses LS disposed on the second cover layer CVL2.

The semiconductor circuit board PCL may include the display area DA in which pixel circuits PXC of the pixels PX are formed. The semiconductor circuit board PCL may further include the non-display area NDA of FIG. 1. For example, the semiconductor circuit board PCL may further include the pads PD located in the non-display area NDA.

The semiconductor circuit board PCL may include a base substrate SB, the pixel circuits PXC disposed or formed in the base substrate SB, and pixel electrodes PXE (or connection lines) electrically connected to the pixel circuits PXC, respectively. The semiconductor circuit board PCL may further include lines electrically connected to the pixels PX.

In an embodiment, the semiconductor circuit board PCL may be formed by a semiconductor process using a silicon wafer. For example, the base substrate SB may be a silicon wafer. In an embodiment, the base substrate SB may be made of monocrystalline silicon.

The pixel circuits PXC may be disposed in the semiconductor circuit board PCL to correspond to pixel areas where the pixels PX are disposed, respectively. In an embodiment, each of the pixel circuits PXC may include a complementary metal-oxide semiconductor (CMOS) circuit formed using a semiconductor process. In an embodiment, each of the pixel circuits PXC may include at least one transistor and at least one capacitor formed using a semiconductor process. FIG. 3 illustrates rough positions of the pixel circuits PXC included in the first pixel PX1, the second pixel PX2, and the third pixel PX3 as an example of elements disposed inside the semiconductor circuit board PCL.

The pixel electrodes PXE may be disposed on the pixel circuits PXC, respectively. The pixel electrodes PXE may be connected to the pixel circuits PXC, respectively. For example, the pixel circuit PXC of each pixel PX may be electrically connected to the pixel electrode PXE of the pixel PX. The pixel electrodes PXE may receive the first driving voltage (for example, a first pixel voltage or an anode voltage) from the pixel circuits PXC, respectively.

In an embodiment, the pixel electrodes PXE may be integral with the pixel circuits PXC, respectively. For example, the pixel electrodes PXE may be electrodes (or lines) exposed by protruding from upper surfaces of the pixel circuits PXC, respectively.

The pixel electrodes PXE may include at least one conductive material. For example, the pixel electrodes PXE may include, but are not limited to, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof.

The pixel electrodes PXE may be electrically connected to the light emitting elements LE through the connection electrodes CNE and the bonding electrodes BDE, respectively. For example, the pixel electrode PXE of each pixel PX may be electrically connected to a light emitting element LE on the bonding electrode BDE of the pixel PX through the connection electrode CNE and the bonding electrode BDE of the pixel PX. In an embodiment, at least one electrode may be further disposed between each bonding electrode BDE and a corresponding light emitting element LE, and each bonding electrode BDE and the corresponding light emitting element LE may be electrically connected to each other via the at least one electrode. For example, a first contact electrode CTE1 and a light emitting element LE may be sequentially disposed on each bonding electrode BDE along the third direction DR3, and each bonding electrode BDE may be electrically connected to the light emitting element LE via the first contact electrode CTE1.

The first cover layer CVL1 may be disposed on the pixel circuits PXC and the pixel electrodes PXE. The first cover layer CVL1 may cover the semiconductor circuit board PCL including the base substrate SB, the pixel circuits PXC, and the pixel electrodes PXE. The first cover layer CVL1 may also be referred to as a “first passivation layer” or a “first insulating layer.”

The first cover layer CVL1 may include openings (for example, contact holes or via holes) that partially expose the pixel electrodes PXE. The openings may be filled with the connection electrodes CNE. For example, the first cover layer CVL1 may surround the connection electrodes CNE.

The first cover layer CVL1 may include at least one insulating material and may have a single-layer or multilayer structure. In an embodiment, the first cover layer CVL1 may include, but is not limited to, an inorganic insulating material (for example, silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or other inorganic insulating materials).

The connection electrodes CNE may connect the semiconductor circuit board PCL and the bonding electrodes BDE. For example, the connection electrodes CNE may be electrically connected between the pixel electrodes PXE of the pixels PX and the bonding electrodes BDE.

In an embodiment, the connection electrodes CNE may include a conductive metal. For example, the connection electrodes CNE may include at least one of gold (Au), copper (Cu), tin (Sn), titanium (Ti), aluminum (Al), and silver (Ag).

The semiconductor circuit board PCL, the connection electrodes CNE, and the first cover layer CVL1 may constitute a lower substrate 110 (for example, a backplane substrate) of the display panel DPN. The light emitting elements LE may be disposed on the lower substrate 110. In an embodiment, the display panel DPN may further include the bonding electrodes BDE disposed on the lower substrate 110, and the light emitting elements LE may be disposed on the bonding electrodes BDE. The lower substrate 110 and the light emitting elements LE may be coupled or connected by the bonding electrodes BDE.

The bonding electrodes BDE may be disposed on the first cover layer CVL1. The bonding electrodes BDE may be disposed separately from each other in the pixel areas where the pixels PX are disposed, respectively. Accordingly, the light emitting elements LE of the pixels PX may be driven individually. Each of the bonding electrodes BDE may be connected to the connection electrode CNE of a corresponding pixel PX. In an embodiment, each bonding electrode BDE may function as an anode of a light emitting element LE or a pixel PX. Each bonding electrode BDE may also be referred to as an “electrode” or a “first electrode.”

Each of the bonding electrodes BDE may be composed of a single layer or multiple layers including a bonding layer BMTL (also referred to as a “bonding metal layer”). For example, each of the bonding electrodes BDE may include a bonding layer BMTL and first and second barrier layers BRL1 and BRL2 disposed on both surfaces of the bonding layer BMTL.

In an embodiment, each of the bonding electrodes BDE may further include a reflective layer RMTL disposed on the bonding layer BMTL. For example, the reflective layer RMTL may be disposed on the second barrier layer BRL2.

In an embodiment, each of the bonding electrodes BDE may further include a third barrier layer BRL3 disposed on the reflective layer RMTL. For example, the third barrier layer BRL3 may be disposed between the reflective layer RMTL and the first contact electrode CTE1.

The bonding layer BMTL may include a conductive material suitable for bonding, for example, a bonding metal. For example, the bonding layer BMTL may include a metal or metal alloy having excellent electrical and thermal conductivity.

In an embodiment, the bonding layer BMTL may have a thickness sufficient to appropriately or readily perform a bonding process. For example, the bonding layer BMTL may have a largest thickness among the layers constituting the bonding electrode BDE. For example, the bonding layer BMTL may have a thickness of about hundreds of (for example, a thickness in a range of about 200 nm to about 500 nm), but embodiments are not limited thereto.

In an embodiment, the bonding layer BMTL may include a gold (Au)-tin (Sn) alloy. The gold (Au)-tin (Sn) alloy has excellent bonding strength and a low melting point. Therefore, it can lower the temperature of a bonding process (for example, a wafer-to-wafer bonding process utilizing the bonding layer BMTL) while appropriately bonding the light emitting elements LE (or an epitaxial layer to be formed into the light emitting elements LE) onto the lower substrate 110. Accordingly, the light emitting elements LE or other elements around the light emitting elements LE can be prevented from being damaged or deteriorated by the bonding process. The gold (Au)-tin (Sn) alloy may exhibit low resistance change to temperature and may have electrically stable characteristics. Therefore, the bonding layer BMTL including the gold (Au)-tin (Sn) alloy can stably electrically and/or physically connect the pixel electrodes PXE and the light emitting elements LE and improve the reliability and operating characteristics of the light emitting elements LE and the pixels PX including the light emitting elements LE. However, the material of the bonding layer BMTL is not limited to the gold (Au)-tin (Sn) alloy. For example, the bonding layer BMTL may also include a metal or alloy, such as titanium (Ti), having a low risk of generating foreign matter due to an etching process or may include other bonding metals having high reliability, such as zirconium (Zr), nickel (Ni), or chromium (Cr).

The first barrier layer BRL1 may be disposed under (or below) the bonding layer BMTL. For example, the first barrier layer BRL1 may be disposed between a connection electrode CNE and the bonding layer BMTL and may cover a lower surface of the bonding layer BMTL.

The second barrier layer BRL2 may be disposed on the bonding layer BMTL. For example, the second barrier layer BRL2 may be disposed between the bonding layer BMTL and the reflective layer RMTL and may cover an upper surface of the bonding layer BMTL and a lower surface of the reflective layer RMTL.

The first barrier layer BRL1 and the second barrier layer BRL2 may include a material suitable for diffusion prevention (for example, intermetallic diffusion prevention) and may include the same material or different materials. Each of the first barrier layer BRL1 and the second barrier layer BRL2 may be formed of a material and/or to a thickness that can secure the conductivity of each bonding electrode BDE. In an embodiment, each of the first barrier layer BRL1 and the second barrier layer BRL2 may include a material having a high intermetallic diffusion prevention effect such as titanium (Ti), titanium nitride (TiN), nickel (Ni) or other diffusion prevention materials and may be formed to a thickness equal to or less than a thickness of the reflective layer RMTL and/or the bonding layer BMTL. For example, each of the first barrier layer BRL1 and the second barrier layer BRL2 may be formed as a thin film including a material suitable for preventing diffusion of a metal included in the bonding layer BMTL and/or the reflective layer RMTL.

The reflective layer RMTL may be disposed on the bonding layer BMTL. A lower surface and an upper surface of the reflective layer RMTL may be covered with the second barrier layer BRL2 and the third barrier layer BRL3, respectively.

The reflective layer RMTL may include a conductive material (for example, a metal) having high light reflectivity. For example, the reflective layer RMTL may include aluminum (Al) or other metals having high light reflectivity (for example, molybdenum (Mo), titanium (Ti), copper (Cu), silver (Ag), magnesium (Mg), platinum (Pt), palladium (Pd), gold (Au), nickel (Ni), neodymium (Nd), iridium (Ir), or chromium (Cr)).

In an embodiment, the reflective layer RMTL may completely cover a lower surface of each of the light emitting elements LE. For example, in plan view, the reflective layer RMTL of the bonding electrode BDE disposed in each pixel PX may have a larger size than the light emitting element LE disposed in the pixel PX and may overlap the light emitting element LE and an area around the light emitting element LE. Since the reflective layer RMTL completely covers the lower surface of each of the light emitting elements LE, it can effectively reflect light that travels downward from each of the light emitting elements LE. Accordingly, the light efficiency of the light emitting elements LE and the pixels PX including the light emitting elements LE can be increased.

The third barrier layer BRL3 may be disposed on the reflective layer RMTL. For example, the third barrier layer BRL3 may be disposed between the reflective layer RMTL and the first contact electrode CTE1 and may cover the upper surface of the reflective layer RMTL.

The third barrier layer BRL3 may include a material suitable for diffusion prevention (for example, intermetallic diffusion prevention) and may be formed of a material and/or to a thickness that can secure conductivity of each bonding electrode BDE. In an embodiment, the third barrier layer BRL3 may include titanium (Ti), titanium nitride (TiN), nickel (Ni), or other diffusion prevention materials. For example, the third barrier layer BRL3 may be formed as a thin film including titanium nitride (TiN) (for example, a thin film having a thickness of about 20 nm or less). Accordingly, it can prevent diffusion of a metal included in the reflective layer RMTL while securing conductivity of each bonding electrode BDE.

In an embodiment, the light emitting elements LE may be disposed on the bonding electrodes BDE, respectively. For example, the first contact electrode CTE1 may be disposed on each bonding electrode BDE, and a light emitting element LE may be disposed on the first contact electrode CTE1. In FIGS. 3 and 4, the first contact electrode CTE1 is illustrated as a separate element from each of the light emitting elements LE, but embodiments are not limited thereto. For example, the first contact electrode CTE1 may also be considered as an element included in each of the light emitting elements LE. The first contact electrode CTE1 may be formed or etched together with each light emitting element LE or may be formed or etched separately from each light emitting element LE.

In an embodiment, each light emitting element LE or each pixel PX may not include the first contact electrode CTE1. The light emitting elements LE may be disposed (e.g., directly disposed) on the bonding electrodes BDE of the pixels PX.

FIGS. 3 and 4 illustrate the display panel DPN having a structure in which the bonding electrodes BDE are disposed on the lower substrate 110 including the semiconductor circuit board PCL, and the light emitting elements LE are coupled (or connected) to the lower substrate 110 by the bonding electrodes BDE. However, the structure of the display panel DPN according to embodiments is not limited thereto. For example, the light emitting elements LE may also be appropriately placed on the lower substrate 110 by utilizing other connection electrodes or lines without using a bonding method.

The first contact electrode CTE1 may be disposed on each bonding electrode BDE. For example, the first contact electrode CTE1 may be disposed between each bonding electrode BDE and each light emitting element LE.

The first contact electrode CTE1 may be disposed on a surface (for example, a lower surface) of a first semiconductor layer SEM1 included in each light emitting element LE. The first contact electrode CTE1 may protect the first semiconductor layer SEM1 and smoothly connect each light emitting element LE to a corresponding bonding electrode BDE.

In an embodiment, the first contact electrode CTE1 may be disposed (e.g., entirely disposed) on a surface of the first semiconductor layer SEM1. For example, the first contact electrode CTE1 may be disposed (e.g., entirely disposed) on the lower surface of the first semiconductor layer SEM1. Accordingly, the first semiconductor layer SEM1 can be appropriately or stably protected. However, embodiments are not limited thereto, and the first contact electrode CTE1 may also be disposed only on a portion of the first semiconductor layer SEM1.

The first contact electrode CTE1 may include a metal, a metal oxide, or other conductive materials. In an embodiment, the first contact electrode CTE1 may include, but is not limited to, a transparent conductive material (for example, indium tin oxide (ITO), indium zinc oxide (IZO), or other transparent conductive materials).

Each of the light emitting elements LE may be disposed on the first contact electrode CTE1 (or the bonding electrode BDE) of a corresponding pixel PX.

Each of the light emitting elements LE may include the first semiconductor layer SEM1, a light emitting layer EML, and a second semiconductor layer SEM2 sequentially disposed on the first contact electrode CTE1. For example, the first semiconductor layer SEM1, the light emitting layer EML, and the second semiconductor layer SEM2 may be sequentially disposed or stacked on the first contact electrode CTE1 along the third direction DR3. The first semiconductor layer SEM1, the light emitting layer EML, and the second semiconductor layer SEM2 may be formed from a semiconductor epitaxial stack or epi-layers formed on a semiconductor substrate by epitaxial growth.

The first semiconductor layer SEM1 may include a semiconductor material doped with a dopant of a first conductivity type. For example, the first semiconductor layer SEM1 may be a first-conductivity type semiconductor layer including a nitride-based semiconductor material, a phosphide-based semiconductor material or other semiconductor materials and further including the dopant of the first conductivity type. In an embodiment, the first semiconductor layer SEM1 may be, but is not limited to, a p-type semiconductor layer (for example, p-GaN) doped with a p-type dopant such as Mg, Zn, Ca, Se, or Ba.

The light emitting layer EML may be disposed on the first semiconductor layer SEM1. For example, the light emitting layer EML may be disposed between the first semiconductor layer SEM1 and the second semiconductor layer SEM2. The light emitting layer EML may emit light through recombination of electron-hole pairs generated according to electrical signals received through the first semiconductor layer SEM1 and the second semiconductor layer SEM2.

The light emitting layer EML may include a nitride-based semiconductor material, a phosphide-based semiconductor material or other semiconductor materials and may have a single or multiple quantum well structure. In an embodiment, the light emitting layer EML may have a multiple quantum well structure including a quantum well layer including InGaN and a barrier layer including GaN, AlGaN or GaAlN, but embodiments are not limited thereto. In an embodiment, in case that the light emitting layer EML may include InGaN, the color of light emitted from the light emitting layer EML may be controlled or changed by adjusting indium content.

The light emitting layer EML may emit light in a visible light wavelength band, for example, light in a wavelength band in a range of about 400 nm to about 900 nm. For example, the light emitting layer EML may emit blue light having a peak wavelength in a range of about 440 nm to about 480 nm, green light having a peak wavelength in a range of about 510 nm to about 550 nm, or red light having a peak wavelength in a range of about 610 nm to about 650 nm. The light emitting layer EML may also emit light in a color or wavelength band other than the colors or wavelength bands described above.

The second semiconductor layer SEM2 may include a semiconductor material doped with a dopant of a second conductivity type. For example, the second semiconductor layer SEM2 may be a second-conductivity type semiconductor layer including a nitride-based semiconductor material, a phosphide-based semiconductor material or other semiconductor materials and further including the dopant of the second conductivity type. In an embodiment, the second semiconductor layer SEM2 may be, but is not limited to, an n-type semiconductor layer (for example, n-GaN) doped with an n-type dopant such as Si, Ge or Sn.

In an embodiment, a second contact electrode CTE2 may be disposed on each light emitting element LE, and the common electrode CME may be disposed on the second contact electrode CTE2. For example, the second semiconductor layer SEM2 of each light emitting element LE may be electrically connected to the common electrode CME through the second contact electrode CTE2.

In FIGS. 3 and 4, the second contact electrode CTE2 is illustrated as a separate element from each light emitting element LE, but embodiments are not limited thereto. For example, the second contact electrode CTE2 may also be considered as an element included in each light emitting element LE. The second contact electrode CTE2 may be formed or etched together with each light emitting element LE or may be formed or etched separately from each light emitting element LE.

In an embodiment, each light emitting element LE or each pixel PX may not include the second contact electrode CTE2. The common electrode CME may be connected (e.g., directly connected) to or in contact with the light emitting elements LE.

The second contact electrode CTE2 may be disposed on a surface (for example, an upper surface) of the second semiconductor layer SEM2. The second contact electrode CTE2 may protect the second semiconductor layer SEM2 and smoothly connect each light emitting element LE to the common electrode CME.

In an embodiment, the second contact electrode CTE2 may be disposed (e.g., entirely disposed) on a surface of the second semiconductor layer SEM2. For example, the second contact electrode CTE2 may be disposed (e.g., entirely disposed) on the upper surface of the second semiconductor layer SEM2. Accordingly, the second semiconductor layer SEM2 can be stably protected. However, embodiments are not limited thereto, and the second contact electrode CTE2 may also be disposed only on a portion of the second semiconductor layer SEM2.

The second contact electrode CTE2 may include a metal, a metal oxide, or other conductive materials. In an embodiment, the second contact electrode CTE2 may be formed of a transparent electrode layer including a transparent conductive material (for example, indium tin oxide (ITO), indium zinc oxide (IZO), or other transparent conductive materials). Accordingly, light generated from each light emitting element LE may be transmitted through the second contact electrode CTE2 and emitted to above each light emitting element LE.

The light emitting elements LE may be surrounded by the passivation layer PSV, etc. For example, the side surfaces of each of the light emitting elements LE may be surrounded by the passivation layer PSV and the reflective film RFL.

The passivation layer PSV may cover the side surfaces of the light emitting elements LE. In an embodiment, the passivation layer PSV may further cover side surfaces of at least one of the bonding electrodes BDE, the first contact electrode CTE1, and the second contact electrode CTE2. For example, the passivation layer PSV may be disposed in the entire display area DA to cover the side surfaces of the light emitting elements LE, the bonding electrodes BDE, the first contact electrode CTE1, and the second contact electrode CTE2.

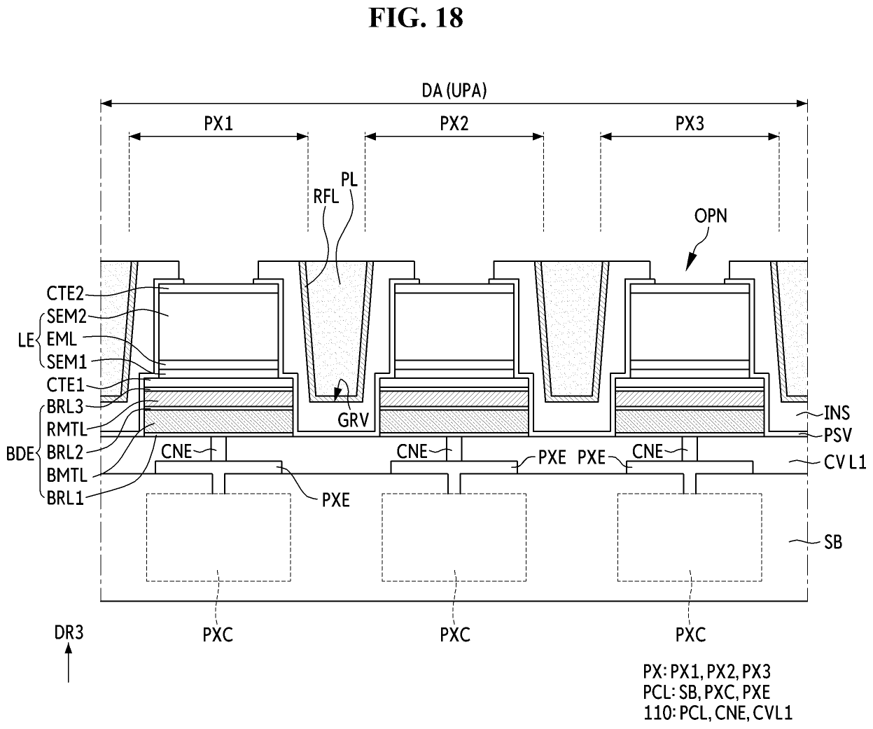

The passivation layer PSV may include an opening that exposes a portion, for example, the upper surface of each of the light emitting elements LE. For example, the passivation layer PSV may include an opening (for example, an opening OPN of FIG. 18) that exposes a portion (for example, a portion of the upper surface) of each light emitting element LE or the second contact electrode CTE2. In each opening of the passivation layer PSV, a light emitting element LE or the second contact electrode CTE2 may be connected to the common electrode CME.

The passivation layer PSV may include at least one insulating material selected from silicon oxide (SiOₓ), silicon nitride (SiNₓ), aluminum oxide (AlₓO_{y}), titanium oxide (TiₓO_{y}) and hafnium oxide (HfOₓ) or may include other insulating materials. The passivation layer PSV may protect the light emitting elements LE and may increase the electrical stability of the light emitting elements LE.

The insulating layer INS may be disposed on the passivation layer PSV. The insulating layer INS may be disposed around the light emitting elements LE. For example, the insulating layer INS may be disposed around the light emitting elements LE to surround each of the light emitting elements LE. For example, the insulating layer INS may be disposed around each of the light emitting elements LE and between the light emitting elements LE and may be disposed in the entire display area DA except for openings formed for connection between the light emitting elements LE and the common electrode CME.

The insulating layer INS may include an opening that exposes a portion, for example, the upper surface of each of the light emitting elements LE. In an embodiment, the insulating layer INS may be formed to a height equal to or greater than a height of each of the light emitting elements LE and may have an opening formed on each of the light emitting elements LE. For example, the insulating layer INS may include an opening (for example, the opening OPN of FIG. 18) that exposes a portion of the upper surface of each of the light emitting elements LE and may cover the other portion of each of the light emitting elements LE.

The insulating layer INS may be composed of a single layer or multiple layers including at least one insulating material. For example, the insulating layer INS may include silicon oxide (SiOₓ), silicon nitride (SiNₓ), silicon oxynitride (SiOₓN_{y}), aluminum oxide (AlₓO_{y}), titanium oxide (TiₓO_{y}) and hafnium oxide (HfOₓ), or other insulating materials.

In an embodiment, the insulating layer INS may include a groove GRV disposed around the light emitting elements LE to surround the light emitting elements LE. In an embodiment, the grooves GRV may be disposed in a mesh shape surrounding the light emitting elements LE in plan view. For example, the groove GRV may have a mesh shape corresponding to the reflective film RFL and the power line PL of FIG. 2 in plan view.

In an embodiment, the groove GRV may be formed to a depth having a value equal to or greater than a thickness of each of the light emitting elements LE. For example, the depth of the groove GRV may be equal to or greater than the thickness of each of the light emitting elements LE, and a bottom surface of the groove GRV may be positioned at the same height as or below (for example, at a lower height) the light emitting elements LE. However, embodiments are not limited thereto. For example, the groove GRV may also be formed to a depth having a value equal to or greater than a thickness of the insulating layer INS. For example, the insulating layer INS may define sidewalls of the groove GRV, and another insulating layer (for example, the passivation layer PSV or the first cover layer CVL1) under the insulating layer INS may define the bottom surface of the groove GRV.

The reflective film RFL may be disposed on the groove GRV of the insulating layer INS. The reflective film RFL may have a shape corresponding to the shape of the groove GRV of the insulating layer INS and may surround the side surfaces of each of the light emitting elements LE. For example, the reflective film RFL may be disposed around the light emitting elements LE and between the light emitting elements LE and may face the side surfaces of each of the light emitting elements LE. For example, the reflective film RFL may have a mesh shape including openings that expose the light emitting elements LE in plan view as illustrated in FIG. 2 and may face the side surfaces of the light emitting elements LE in cross section as illustrated in FIGS. 3 and 4.

The reflective film RFL may recycle light generated from each of the light emitting elements LE and traveling in a lateral direction by reflecting the light. The light emission efficiency of each of the light emitting elements LE (for example, the ratio of light emitted to above each light emitting element LE through the second contact electrode CTE2 and the common electrode CME) may be increased by the reflective film RFL.

In an embodiment, a lowest height of the reflective film RFL may be equal to or less than that of each of the light emitting elements LE. For example, a bottom surface of the reflective film RFL located on the bottom surface of the groove GRV may be disposed at the same height as or below (for example, at a lower height) the light emitting elements LE. A highest height (for example, a height of an upper surface) of the reflective film RFL may be greater than that of each of the light emitting elements LE. Accordingly, the reflective film RFL may surround (e.g., entirely or completely surround) the side surfaces of each of the light emitting elements LE. As a result, light emitted from the light emitting elements LE in the lateral direction can be more effectively reflected.

In an embodiment, the reflective film RFL may include a metal having high reflectivity, such as aluminum (Al). In case that the reflective film RFL may include a conductive material such as a metal, it may be electrically connected to the power line PL. Accordingly, the reflective film RFL may serve as an auxiliary power line while lowering the resistance of the power line PL.

In an embodiment, the reflective film RFL may include distributed Bragg reflectors (DBR). For example, the reflective film RFL may include at least one pair (for example, two or more pairs) of a first layer and a second layer having different refractive indices and disposed alternately or sequentially. One of the first layer and the second layer may be a low refractive index layer, and the other may be a high refractive index layer having a higher refractive index than the low refractive index layer. The first layer and the second layer may be made of an inorganic film, for example, silicon nitride (SiNₓ), silicon oxynitride (SiON), silicon oxide (SiOₓ), titanium oxide (TiOₓ), or aluminum oxide (AlOₓ).

In an embodiment, the reflective film RFL may have a substantially smooth surface as illustrated in FIG. 3. In an embodiment, the reflective film RFL may include a surface having a regular or irregular textured pattern TXP as illustrated in FIG. 4 and may have surface roughness according to the textured pattern TXP. Since the reflective film RFL has surface roughness, light reflectance by the reflective film RFL may be increased. For example, the light reflectance of the reflective film RFL may be increased by diffuse reflection by the textured pattern TXP. Accordingly, a light output ratio of the pixels PX may be increased.

In embodiments, the reflective film RFL is formed while the light emitting elements LE are stably covered with the passivation layer PSV and the insulating layer INS. Therefore, it is possible to effectively prevent a short-circuit defect caused by a byproduct (for example, a conductive residue) or a short-circuit defect of the light emitting elements LE caused by a byproduct during an etching process of the reflective film RFL.

The power line PL may be disposed on the reflective film RFL and may be disposed inside the groove GRV of the insulating layer INS. For example, the power line PL may be disposed (e.g., directly disposed) on the reflective film RFL and may fill the groove GRV of the insulating layer INS.

In an embodiment, the reflective film RFL may include a conductive material such as a metal, and the power line PL may be disposed (e.g., directly disposed) on the reflective film RFL. The reflective film RFL and the power line PL may be electrically connected to each other. Accordingly, the reflective film RFL may also function as an auxiliary power line, thereby preventing or reducing a voltage drop of the common voltage applied to the power line PL.

The power line PL may have a shape corresponding to the groove GRV of the insulating layer INS and the reflective film RFL. For example, the power line PL may have a mesh shape including openings that expose the light emitting elements LE in plan view as illustrated in FIG. 2 and may completely fill the groove GRV of the insulating layer INS in cross section as illustrated in FIGS. 3 and 4.

The common electrode CME may be disposed on the light emitting elements LE, the second contact electrodes CTE2, the reflective film RFL, the power line PL, and/or the insulating layer INS.

In an embodiment, the common electrode CME may be disposed in the entire display area DA. For example, the common electrode CME may be a common layer shared by the light emitting elements LE of the display area DA and the pixels PX including the light emitting elements LE.

The common electrode CME may be electrically connected to the light emitting elements LE. For example, openings may be formed in the passivation layer PSV and the insulating layer INS above the light emitting elements LE, respectively, and the common electrode CME may be connected to the second contact electrodes CTE2 (or the light emitting elements LE) in the openings.

In an embodiment, the common electrode CME may be electrically connected to the second contact electrodes CTE2 and may be electrically connected to the second semiconductor layers SEM2 of the light emitting elements LE through the second contact electrodes CTE2. In an embodiment, the pixels PX may not include the second contact electrodes CTE2, and the common electrode CME may be connected (e.g., directly connected) to the second semiconductor layer SEM2 of each of the light emitting elements LE. For example, the common electrode CME may contact the second contact electrodes CTE2 or the light emitting elements LE in the openings of the passivation layer PSV and the insulating layer INS.

The common electrode CME may be electrically connected to the power line PL. For example, the common electrode CME may be disposed (e.g., directly disposed) on the power line PL to contact the power line PL.

The common electrode CME may include a transparent conductive material that can transmit light. For example, the common electrode CME may be made of indium tin oxide (ITO), indium zinc oxide (IZO), or other transparent conductive materials. In an embodiment, the common electrode CME may function as a cathode of each of the light emitting elements LE or the pixels PX.

The second cover layer CVL2 may be disposed on the common electrode CME. In an embodiment, the second cover layer CVL2 may be disposed in the entire display area DA to cover the common electrode CME. In an embodiment, the second cover layer CVL2 may also be disposed in a peripheral area (for example, the peripheral area PHA of FIG. 1). The second cover layer CVL2 may also be referred to as a “second passivation layer” or a “second insulating layer.”

In an embodiment, an upper surface of the second cover layer CVL2 may be substantially flat. For example, the second cover layer CVL2 may be formed of a material and/or to a thickness suitable to have a substantially flat upper surface or may be planarized by a planarization process performed after it is formed.

The second cover layer CVL2 may include at least one insulating material and may have a single-layer or multilayer structure. In an embodiment, the second cover layer CVL2 may include, but is not limited to, an inorganic insulating material (for example, silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or other inorganic insulating materials).

The lenses LS may be disposed on the second cover layer CVL2. For example, the lenses LS respectively overlapping the light emitting elements LE may be disposed on the second cover layer CVL2. In an embodiment, each lens LS may have a size corresponding to that of the emission area of each pixel PX and may completely overlap the light emitting element LE disposed in each pixel PX. For example, each lens LS may be a micro lens corresponding to the size of each of the light emitting elements LE. In an embodiment, each lens LS may have a larger size than each light emitting element LE and cover a light emitting element LE and an area around the light emitting element LE in plan view.

In an embodiment, the lenses LS may be micro lenses in the form of convex lenses provided above the light emitting elements LE. However, the type, shape, and/or size of the lenses LS are not limited thereto. The lenses LS disposed above the light emitting elements LE can control and/or improve the light output characteristics of the pixels PX.

The lenses LS may be made of a transparent material to allow light incident from the light emitting elements LE to pass therethrough. For example, the lenses LS may be made of glass, plastic, ceramic or other materials and may be made of an optical material having a high refractive index.

In an embodiment, the display panel DPN or the display device 10 including the display panel DPN may further include additional elements. For example, the display panel DPN or the display device 10 including the display panel DPN may further include a light conversion layer or a color filter disposed above the pixels PX (or the light emitting elements LE).

According to the above-described embodiments, since the reflective film RFL is disposed on the groove GRV of the insulating layer INS, it can appropriately reflect light emitted in the lateral direction of the light emitting elements LE without covering the upper surfaces of the light emitting elements LE. Accordingly, emission angles θ1 and 02 at which light can be emitted upward from the light emitting elements LE may increase, thereby increasing the amount of light emitted from the light emitting elements LE. For example, according to embodiments, the amount of light emitted upward from the light emitting elements LE and reaching the lenses LS may increase. Accordingly, the light efficiency of the light emitting elements LE and the pixels PX including the light emitting elements LE can be increased.

According to the above-described embodiments, the reflective film RFL can prevent light leakage or light interference between the pixels PX. Accordingly, color mixing of light emitted from the pixels PX can be prevented.

According to the above-described embodiments, the light emitting elements LE and the reflective film RFL may be appropriately spaced apart or separated by the passivation layer PSV and the insulating layer INS. Accordingly, electrical stability between the light emitting elements LE and the reflective film RFL can be secured, and a short-circuit defect can be prevented.

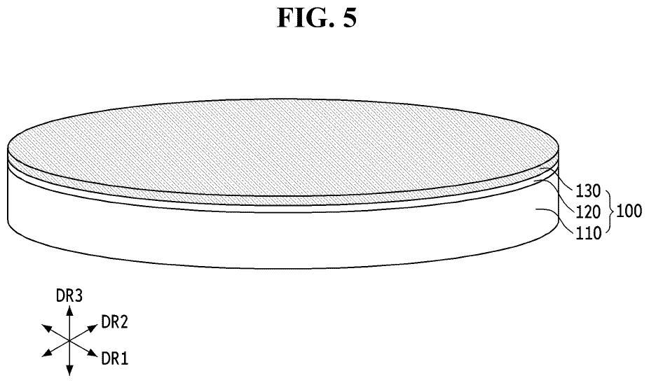

FIGS. 5 through 7 are schematic perspective views illustrating a method of manufacturing a display device according to an embodiment. For example, FIGS. 5 through 7 illustrate operations of preparing a first substrate 100 and a second substrate 200 for manufacturing a display panel DPN according to an embodiment and placing the second substrate 200 on the first substrate 100.

In an embodiment, the first substrate 100 and the second substrate 200 of FIGS. 5 through 7 may include cell areas for simultaneously manufacturing display panels DPN. However, embodiments are not limited thereto. For example, the first substrate 100 and the second substrate 200 may also have a size corresponding to that of a single display panel DPN.

Referring to FIG. 5, the first substrate 100 may be prepared. The first substrate 100 may include a lower substrate 110 of at least one display panel DPN, a first barrier material layer 120, and a first bonding material layer 130 (also referred to as a “first bonding metal layer”). The first barrier material layer 120 and the first bonding material layer 130 may be sequentially disposed or formed on the lower substrate 110 along the third direction DR3.

In an embodiment, the lower substrate 110 may include a semiconductor circuit board PCL as illustrated in FIGS. 3 and 4. The lower substrate 110 may further include connection electrodes CNE and a first cover layer CVL1 on the semiconductor circuit board PCL. For example, as illustrated in FIGS. 3 and 4, the semiconductor circuit board PCL including a base substrate SB, pixel circuits PXC and pixel electrodes PXE may be prepared, and the first cover layer CVL1 and the connection electrodes CNE may be formed on the semiconductor circuit board PCL to prepare the lower substrate 110. The lower substrate 110 may include a cell area for forming at least one display panel DPN. For example, the lower substrate 110 of FIG. 5 may be prepared in a size and shape including cell areas for simultaneously manufacturing display panels DPN. Each of the cell areas may include the pixel circuits PXC, the pixel electrodes PXE, the connection electrodes CNE, and the first cover layer CVL.

The first barrier material layer 120 and the first bonding material layer 130 may be formed to form bonding electrodes BDE of pixels PX, and lower layers of each of the bonding electrodes BDE may be formed from the first barrier material layer 120 and the first bonding material layer 130. For example, the first barrier layer BRL1 and a lower portion of the bonding layer BMTL of FIGS. 3 and 4 may be formed from the first barrier material layer 120 and the first bonding material layer 130, respectively.

The first barrier material layer 120 may be formed using a material described above as the material of the first barrier layer BRL1. The first barrier material layer 120 may be patterned into the first barrier layer BRL1 of each of the bonding electrodes BDE by an etching process performed after a bonding process.

The first bonding material layer 130 may be formed using a material described above as the material of the bonding layer BMTL. For example, the first bonding material layer 130 may be made of a gold (Au)-tin (Sn) alloy, titanium (Ti), zirconium (Zr), nickel (Ni), chromium (Cr), or other bonding metals. The first bonding material layer 130 may be formed to a thickness suitable for the bonding process. For example, the first bonding material layer 130 may be formed to a thickness in a range of about 100 nm to about 300 nm (for example, about 200 nm), but embodiments are not limited thereto. The first bonding material layer 130 may be patterned into the bonding layer BMTL (for example, the lower portion of the bonding layer BMTL) of each of the bonding electrodes BDE by the bonding process and an etching process performed after the bonding process.

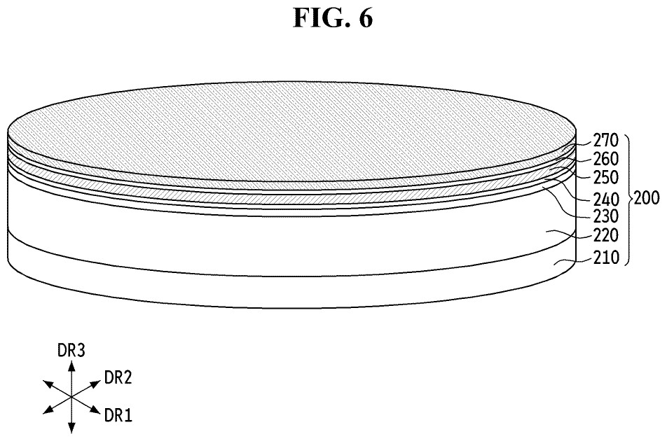

Referring to FIG. 6, the second substrate 200 for forming light emitting elements LE of at least one display panel DPN may be prepared. The second substrate 200 may include a semiconductor substrate 210, an epi-layer 220, a first contact material layer 230, a third barrier material layer 240, a reflective material layer 250, a second barrier material layer 260, and a second bonding material layer 270 (also referred to as a “second bonding metal layer”). The epi-layer 220, the first contact material layer 230, the third barrier material layer 240, the reflective material layer 250, the second barrier material layer 260, and the second bonding material layer 270 may be sequentially disposed or formed on the semiconductor substrate 210.

The semiconductor substrate 210 may be a manufacturing substrate for manufacturing the light emitting elements LE. For example, the semiconductor substrate 210 may be a growth substrate suitable for epitaxial growth.

In an embodiment, the semiconductor substrate 210 may include a material such as GaAs, silicon (Si), sapphire, SiC, GaN, or ZnO. For example, the semiconductor substrate 210 may be a silicon or sapphire substrate. In case that the epitaxial growth of the epi-layer 220 for manufacturing the light emitting elements LE can be smoothly performed, the type or material of the semiconductor substrate 210 is not particularly limited.

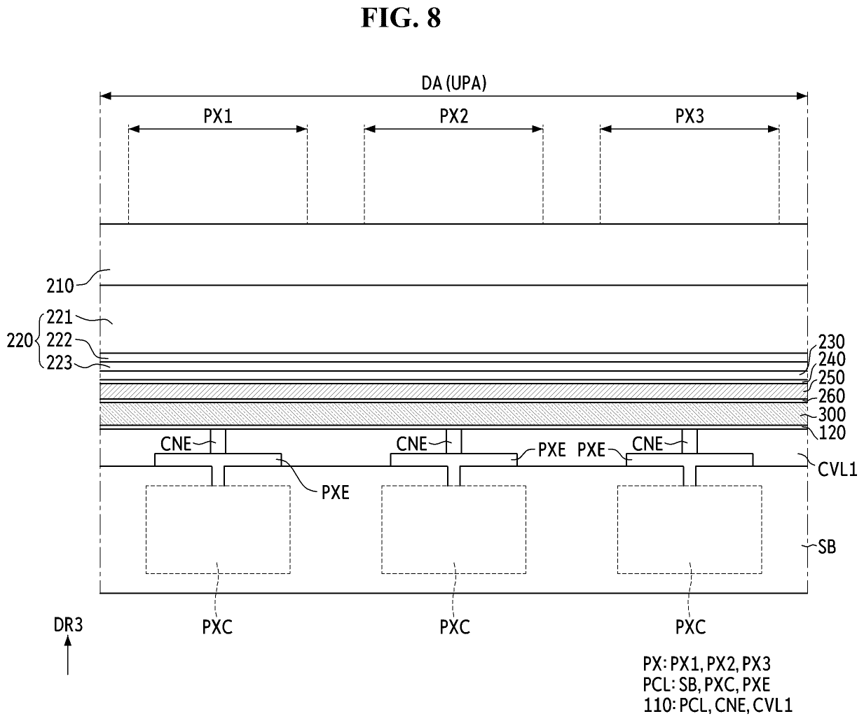

The epi-layer 220 may be formed to form semiconductor layers of each of the light emitting elements LE. For example, the first semiconductor layer SEM1, the light emitting layer EML, and the second semiconductor layer SEM2 of each of the light emitting elements LE illustrated in FIGS. 3 and 4 may be formed from the epi-layer 220. The epi-layer 220 may include a third epi-layer (a third epi-layer 221 of FIG. 8) for forming the second semiconductor layers SEM2 of the light emitting elements LE, a second epi-layer (a second epi-layer 222 of FIG. 8) for forming the light emitting layers EML of the light emitting elements LE, and a first epi-layer (a first epi-layer 223 of FIG. 8) for forming the first semiconductor layers SEM1 of the light emitting elements LE. For example, the epi-layer 220 may be formed on the semiconductor substrate 210 by epitaxial growth using materials described above as the materials of the second semiconductor layers SEM2, the light emitting layers EML and the first semiconductor layers SEM1 of the light emitting elements LE.

The first contact material layer 230, the third barrier material layer 240, the reflective material layer 250, the second barrier material layer 260, and the second bonding material layer 270 may be formed to form first contact electrodes CTE1 and the bonding electrodes BDE of the pixels PX. For example, the first contact electrodes CTE1 may be formed from the first contact material layer 230. Upper layers of each of the bonding electrodes BDE, for example, a third barrier layer BRL3, a reflective layer RMTL, a second barrier layer BRL2, and an upper portion of the bonding layer BMTL may be formed from the third barrier material layer 240, the reflective material layer 250, the second barrier material layer 260, and the second bonding material layer 270, respectively.

The first contact material layer 230 may be formed using a material (for example, ITO, etc.) described above as the material of the first contact electrodes CTE1. In an embodiment, the first contact material layer 230 may be formed to a thickness suitable for functioning as contact electrodes for smoothly connecting the light emitting elements LE to the bonding electrodes BDE, respectively. For example, the first contact material layer 230 may be formed to a thickness of about 100 nm, but embodiments are not limited thereto. The first contact material layer 230 may be patterned into the first contact electrode CTE1 of each of the pixels PX by an etching process performed after the bonding process.

The third barrier material layer 240 may be formed using a material (for example, TiN, etc.) described above as the material of the third barrier layer BRL3. In an embodiment, the third barrier material layer 240 may be a thin film formed to a limited thickness, for example, a thickness of about 20 nm or less, but embodiments are not limited thereto. The third barrier material layer 240 may be patterned into the third barrier layer BRL3 of each of the bonding electrodes BDE by an etching process performed after the bonding process.

The reflective material layer 250 may be formed using a material (for example, Al, etc.) described above as the material of the reflective layer RMTL. In an embodiment, the reflective material layer 250 may be formed to a thickness for appropriately reflecting light emitted from the light emitting elements LE (for example, a thickness for securing a target range of light reflectance). For example, the reflective material layer 250 may be formed to a thickness in a range of about 100 nm to about 200 nm, but embodiments are not limited thereto. The reflective material layer 250 may be patterned into the reflective layer RMTL of each of the bonding electrodes BDE by an etching process performed after the bonding process.

The second barrier material layer 260 may be formed using a material (for example, Ti, etc.) described above as the material of the second barrier layer BRL2. The second barrier material layer 260 may be patterned into the second barrier layer BRL2 of each of the bonding electrodes BDE by an etching process performed after the bonding process.

The second bonding material layer 270 may be formed using a material described above as the material of the bonding layer BMTL. For example, the second bonding material layer 270 may be made of a gold (Au)-tin (Sn) alloy, titanium (Ti), zirconium (Zr), nickel (Ni), chromium (Cr), or other bonding metals. In an embodiment, the first bonding material layer 130 and the second bonding material layer 270 may include a same material. The second bonding material layer 270 may be formed to a thickness suitable for the bonding process. For example, the second bonding material layer 270 may be formed to a thickness in a range of about 100 nm to about 300 nm (for example, about 200 nm), but embodiments are not limited thereto. The second bonding material layer 270 may be patterned into the bonding layer BMTL (for example, the upper portion of the bonding layer BMTL) by an etching process performed after the bonding process.

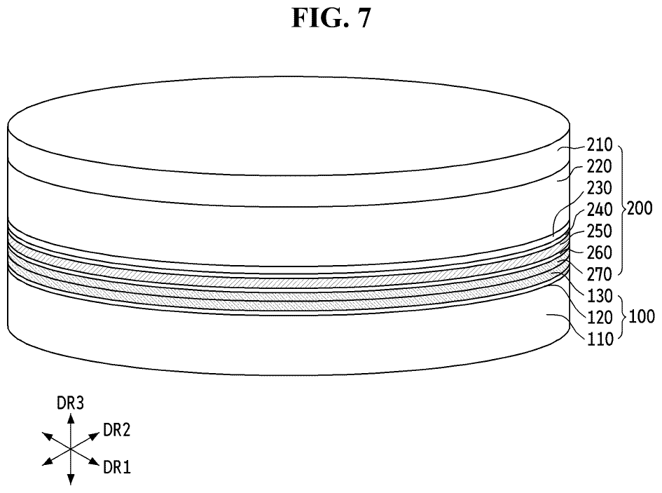

Referring to FIG. 7, the first substrate 100 and the second substrate 200 may be placed to face each other. For example, after the first substrate 100 and the second substrate 200 are aligned such that the first bonding material layer 130 of the first substrate 100 and the second bonding material layer 270 of the second substrate 200 face each other, the first bonding material layer 130 and the second bonding material layer 270 may be brought into contact or close contact with each other.

The first bonding material layer 130 and the second bonding material layer 270 may be melted to bond (or join) the first substrate 100 and the second substrate 200. For example, after the second substrate 200 is placed on the first substrate 100, heat and pressure may be applied to bond the first substrate 100 and the second substrate 200 together.

FIGS. 8 through 20 are schematic cross-sectional views illustrating the method of manufacturing the display device according to the embodiment. For example, FIGS. 8 through 20 illustrate a pixel process performed after the first substrate 100 and the second substrate 200 are bonded together. The pixel process may include a process of forming the pixels PX including the light emitting elements LE on the lower substrate 110 in each cell area.

FIGS. 8 through 20 illustrate only a portion of one cell area, for example, illustrate a unit pixel area UPA located in one cell area. The unit pixel area UPA of FIGS. 8 through 20 may correspond to the unit pixel area UPA of FIG. 3. The display panel DPN according to the embodiment of FIG. 4 may be manufactured in a similar manner to the display panel DPN according to the embodiment of FIG. 3. For example, the display panel DPN according to the embodiment of FIG. 4 may be manufactured in substantially the same manner as the display panel DPN according to the embodiment of FIG. 3, except that a process for forming the textured pattern TXP on a surface of the reflective film RFL is added.

FIGS. 8 through 20 disclose an embodiment in which light emitting elements LE of a first pixel PX1, a second pixel PX2, and a third pixel PX3 are formed from the epi-layer 220 formed on one semiconductor substrate 210, but embodiments are not limited thereto. For example, the light emitting elements LE of the first pixel PX1, the second pixel PX2, and the third pixel PX3 may also be formed from different epi-layers 220 and placed on the bonding electrodes BDE or the lower substrate 110.

Referring to FIGS. 7 and 8, the second substrate 200 may be bonded onto the first substrate 100 by bonding the first bonding material layer 130 and the second bonding material layer 270 together to form a bonding layer 300. For example, a bonding process may be performed by applying heat and pressure while the second substrate 200 is placed on the first substrate 100 so that the first bonding material layer 130 and the second bonding material layer 270 contact each other. Accordingly, the first bonding material layer 130 and the second bonding material layer 270 may be melted to form one bonding layer 300. The bonding layer 300 may be patterned into the bonding layer BMTL of each of the bonding electrodes BDE by an etching process performed after the bonding process.

FIG. 8 illustrates the structure of the epi-layer 220 in more detail. For example, the epi-layer 220 may include a first epi-layer 223 (for example, a p-type semiconductor layer) for forming the first semiconductor layers SEM1 of the light emitting elements LE, a second epi-layer 222 (for example, a multiple quantum well layer including a quantum well layer and a barrier layer) for forming the light emitting layers EML of the light emitting elements LE, and a third epi-layer 221 (for example, an n-type semiconductor layer) for forming the second semiconductor layers SEM2 of the light emitting elements LE.

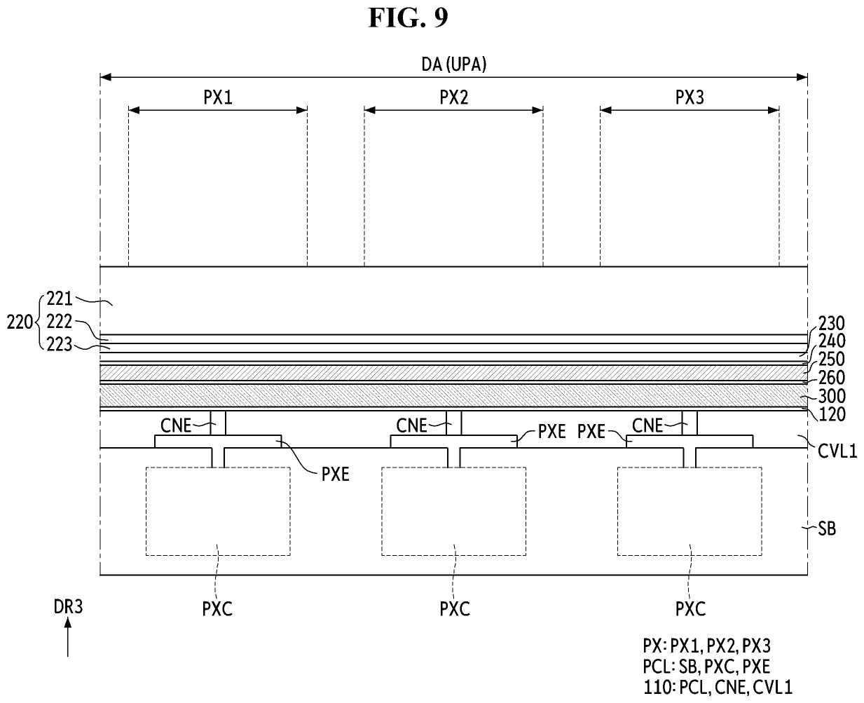

Referring to FIGS. 8 and 9, after the bonding layer 300 is formed, the semiconductor substrate 210 may be separated from the epi-layer 220. Accordingly, the semiconductor substrate 210 may be removed from the epi-layer 220.

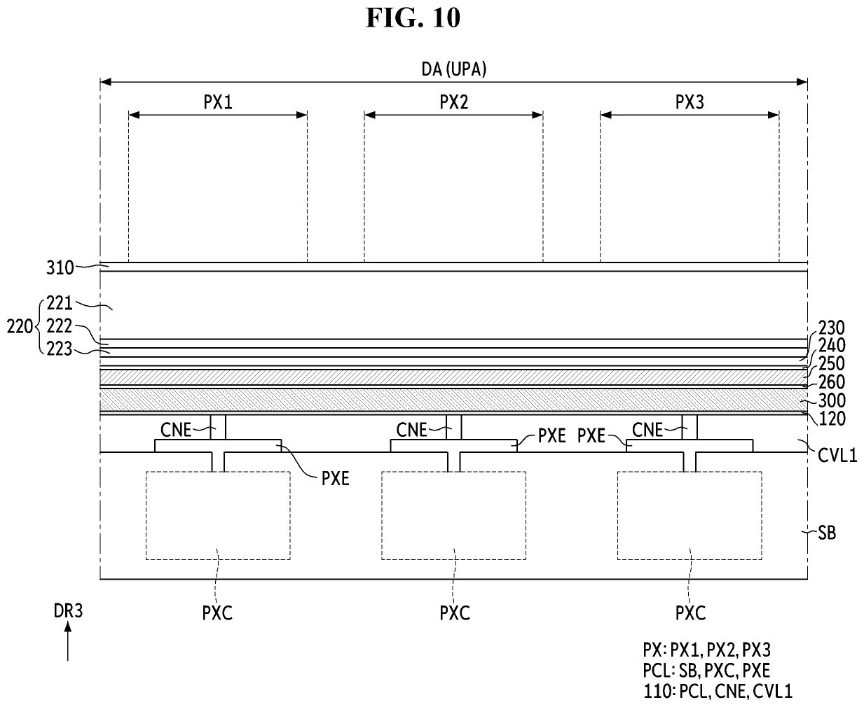

Referring to FIG. 10, a second contact material layer 310 may be formed (for example, deposited) on the epi-layer 220. The second contact material layer 310 may be formed to form second contact electrodes CTE2 of the pixels PX. The second contact electrode CTE2 of each of the pixels PX may be formed from the second contact material layer 310.

The second contact material layer 310 may be formed using a material (for example, ITO, etc.) described above as the material of the second contact electrodes CTE2. In an embodiment, the second contact material layer 310 may be formed to a thickness suitable for functioning as contact electrodes for smoothly connecting the light emitting elements LE to a common electrode CME. The second contact material layer 310 may be formed to allow light emitted from the light emitting elements LE to pass therethrough. For example, the second contact material layer 310 may include a transparent conductive material and may be formed to a thickness of about 100 nm, but embodiments are not limited thereto. In an embodiment, in case that a display panel DPN that does not include the second contact electrodes CTE2 (for example, a display panel DPN in which the common electrode CME is directly disposed on the light emitting elements LE) is manufactured, a process for forming the second contact material layer 310 may be omitted.

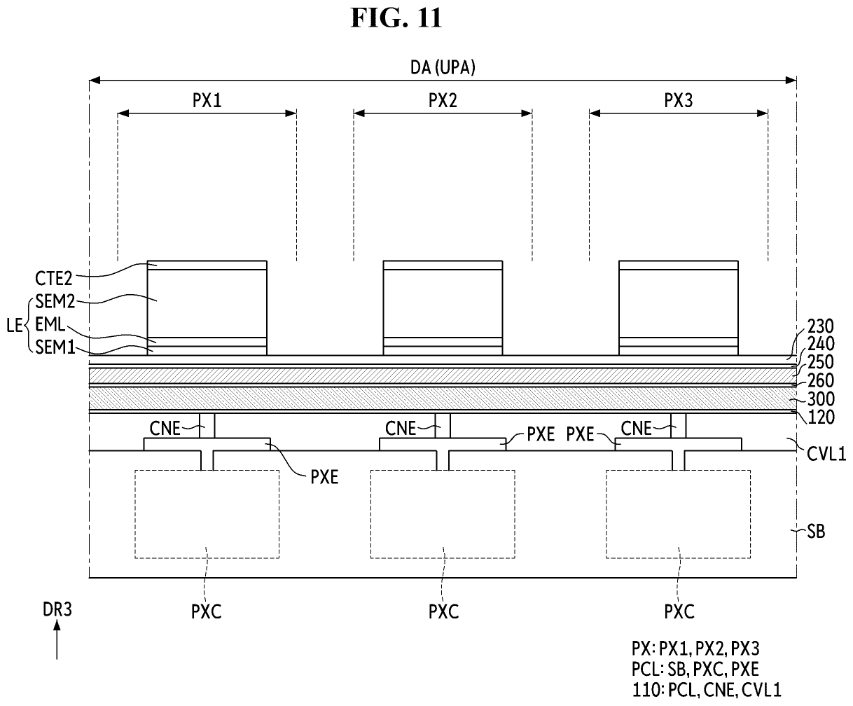

Referring to FIGS. 10 and 11, the second contact material layer 310 and the epi-layer 220 may be etched to form the second contact electrode CTE2 and the light emitting element LE of each of the pixels PX. In an embodiment, the second contact material layer 310 and the epi-layer 220 may be etched by an etching process using one mask. For example, the second contact material layer 310 and the epi-layer 220 may be etched simultaneously and/or continuously by an etching process using a first mask. As a result, the second contact electrode CTE2 and the light emitting element LE of each of the pixels PX may be formed.

In the etching process using the first mask, the type or ratio of an etching gas may vary according to the material of each layer to be etched. For example, the type or ratio of the etching gas may be adjusted or changed so that each layer to be etched can be appropriately etched.

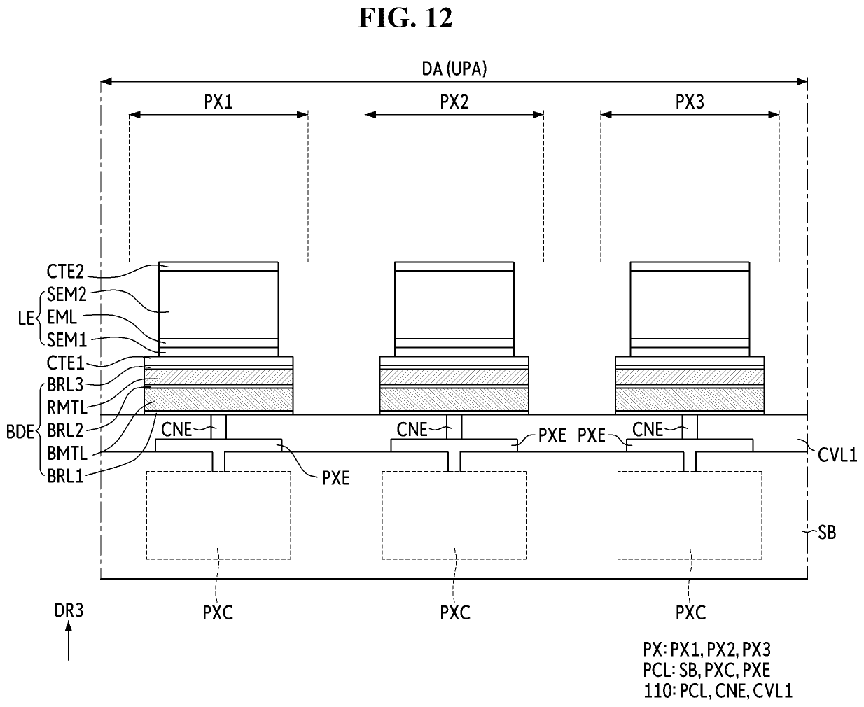

Referring to FIGS. 11 and 12, the first contact material layer 230, the third barrier material layer 240, the reflective material layer 250, the second barrier material layer 260, the bonding layer 300, and the first barrier material layer 120 may be etched to form the first contact electrode CTE1 and the bonding electrode BDE of each of the pixels PX. In an embodiment, the first contact material layer 230, the third barrier material layer 240, the reflective material layer 250, the second barrier material layer 260, the bonding layer 300, and the first barrier material layer 120 may be etched by an etching process using one mask. For example, the first contact material layer 230, the third barrier material layer 240, the reflective material layer 250, the second barrier material layer 260, the bonding layer 300, and the first barrier material layer 120 may be etched simultaneously and/or continuously by an etching process using a second mask. Accordingly, the first contact electrode CTE1 and the bonding electrode BDE of each of the pixels PX may be formed.

The type or ratio of an etching gas may vary according to the material of each layer to be etched in the etching process using the second mask. For example, the type or ratio of the etching gas may be adjusted or changed so that each layer to be etched can be appropriately etched.

FIGS. 11 and 12 illustrate an embodiment in which an additional mask process is performed after the light emitting elements LE are formed to etch the first contact electrodes CTE1 and the bonding electrodes BDE, but embodiments are not limited thereto. For example, the number of mask processes performed to etch the second contact material layer 310, the epi-layer 220, the first contact material layer 230, the third barrier material layer 240, the reflective material layer 250, the second barrier material layer 260, the bonding layer 300 and the first barrier material layer 120 and/or the resultant shapes or sizes of the second contact electrodes CTE2, the light emitting elements LE, the first contact electrodes CTE1 and the bonding electrodes BDE may vary according to embodiments.

FIGS. 5 through 12 disclose an embodiment in which the second substrate 200 including the epi-layer 220 and the second bonding material layer 270 is bonded onto the first substrate 100 including the lower substrate 110 and the first bonding material layer 130, and the epi-layer 220 and the bonding layer 300 are etched to form the light emitting elements LE and the bonding electrodes BDE. However, the method of placing or forming the light emitting elements LE on the lower substrate 110 is not limited thereto. For example, after the light emitting elements LE are formed by etching the epi-layer 220 on the semiconductor substrate 210, they may be placed on the lower substrate 110.

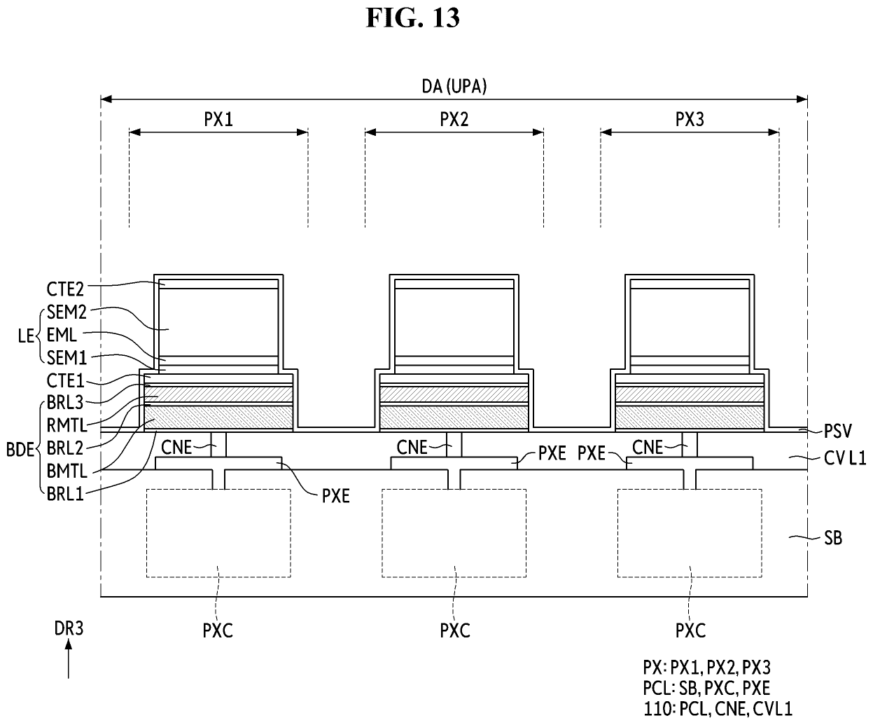

Referring to FIG. 13, a passivation layer PSV may be formed to cover side surfaces of the light emitting elements LE. The passivation layer PSV may be formed using a material (for example, AlₓO_{y} (for example, Al₂O₃) or other insulating materials) described above as the material of the passivation layer PSV.

In an embodiment, the passivation layer PSV may be formed in the entire display area DA and may be etched in a subsequent process to expose a portion of each of the light emitting elements LE. For example, the passivation layer PSV may cover (e.g., entirely cover) the bonding electrodes BDE, the first contact electrodes CTE1, the light emitting elements LE, and the second contact electrodes CTE2.

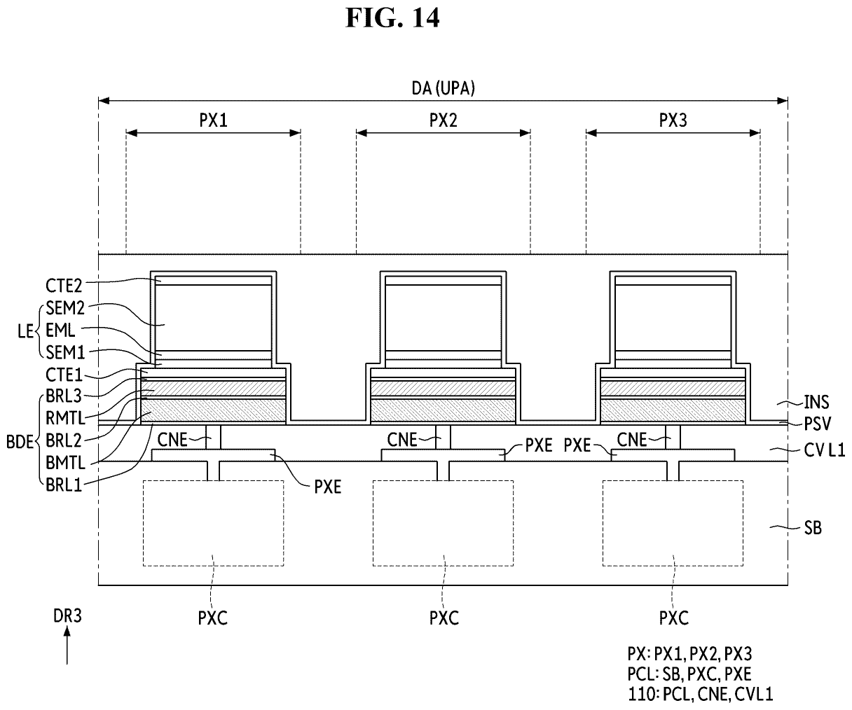

Referring to FIG. 14, an insulating layer INS may be formed on the passivation layer PSV. In an embodiment, the insulating layer INS may be formed (e.g., entirely formed) on the lower substrate 110 to fill a space between the light emitting elements LE. For example, the insulating layer INS may first be formed in the entire display area DA.

In an embodiment, the insulating layer INS may be formed to a height greater than a height of the light emitting elements LE so as to completely cover the light emitting elements LE. For example, the insulating layer INS may cover the bonding electrodes BDE, the light emitting elements LE and the passivation layer PSV of the pixels PX and may also fill the space between the light emitting elements LE. The insulating layer INS may be formed using a material described above or other insulating materials.

In an embodiment, the insulating layer INS may be formed to be substantially flat. For example, the insulating layer INS may be formed of a material and/or to a thickness suitable for having a flat upper surface or may be planarized by a planarization process (for example, a chemical mechanical polishing (CMP) process) performed after it is formed.

For example, after the insulating layer INS is formed using an inorganic insulating material such as SiOₓ (for example, SiO₂) to a height greater than the height of the light emitting elements LE, the upper surface of the insulating layer INS may be planarized by a planarization process (for example, a CMP process). By way of example, the insulating layer INS may be formed using an inorganic insulating material to a sufficient thickness so that the upper surface of the insulating layer INS is substantially flat. However, embodiments are not limited thereto. For example, the insulating layer INS may include at least one organic insulating layer including an organic insulating material. Accordingly, the insulating layer INS may be formed to be substantially flat.

However, embodiments are not limited thereto. For example, the insulating layer INS may be formed to have a step due to the light emitting elements LE.

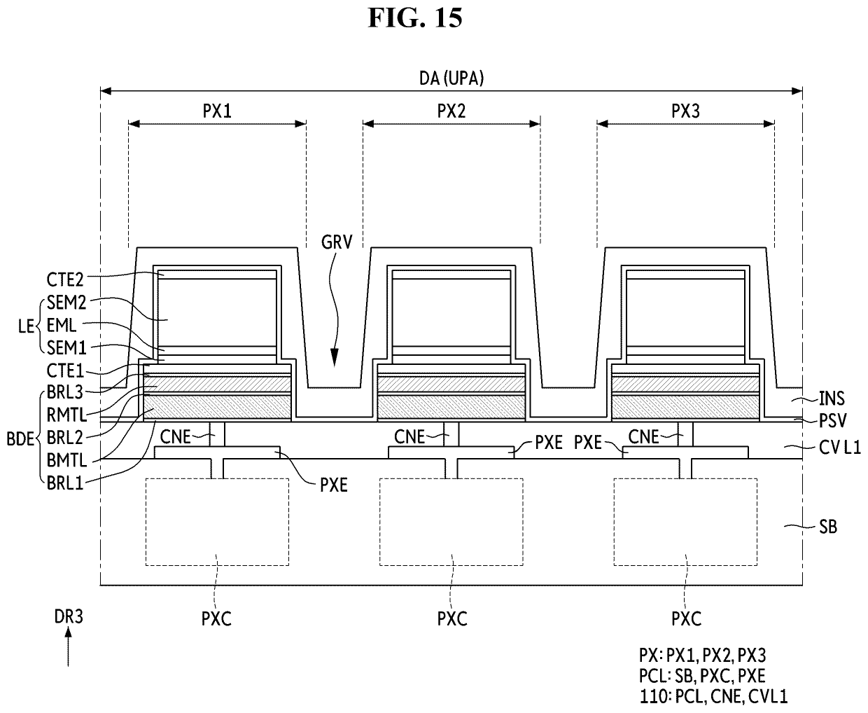

Referring to FIG. 15, a groove GRV may be formed to surround the light emitting elements LE by etching the insulating layer INS. For example, in plan view (or when viewed in the third direction DR3), the insulating layer INS may be etched to a given thickness to surround each of the light emitting elements LE in a non-overlap portion (for example, between and/or around the light emitting elements LE). Accordingly, the groove GRV may be formed in the insulating layer INS to surround the light emitting elements LE. For example, the groove GRV may have a mesh shape surrounding the light emitting elements LE in plan view.

In an embodiment, the insulating layer INS may be etched to a depth (or a level) equal to or less than a height at which the light emitting elements LE are disposed. Accordingly, a bottom surface of the groove GRV may be disposed at the same height as or below the light emitting elements LE. For example, the bottom surface of the groove GRV may be disposed at a similar height to the reflective layer RMTL of each of the bonding electrodes BDE or may be disposed below the reflective layer RMTL.

FIGS. 14 and 15 disclose an embodiment in which after the insulating layer INS is formed to a height greater than the height of the light emitting elements LE to completely fill the space between the light emitting elements LE, it is etched to form the groove GRV. However, embodiments are not limited thereto. For example, the insulating layer INS may also be formed using an inorganic insulating material to a thickness less than a thickness of the bonding electrodes BDE or the light emitting elements LE. Accordingly, from its formation stage, the insulating layer INS may be formed to have bends including the groove GRV between the light emitting elements LE. The process for forming the groove GRV in the insulating layer INS may be omitted. By way of example, even in case that the insulating layer INS is formed to include the groove GRV between the light emitting elements LE, an etching process may also be performed to adjust or change the shape or depth of the groove GRV before the formation of a reflective film RFL in order to form the reflective film RFL and/or a power line PL in a desired shape.

FIGS. 14 and 15 disclose an embodiment in which the insulating layer INS is etched only by a given thickness to form the groove GRV. However, embodiments are not limited thereto. For example, in an embodiment, the insulating layer INS may be etched by its entire thickness around the light emitting elements LE to form the groove GRV. The insulating layer INS may define sidewalls of the groove GRV, and the passivation layer PSV or the first cover layer CVL1 may define the bottom surface of the groove GRV.

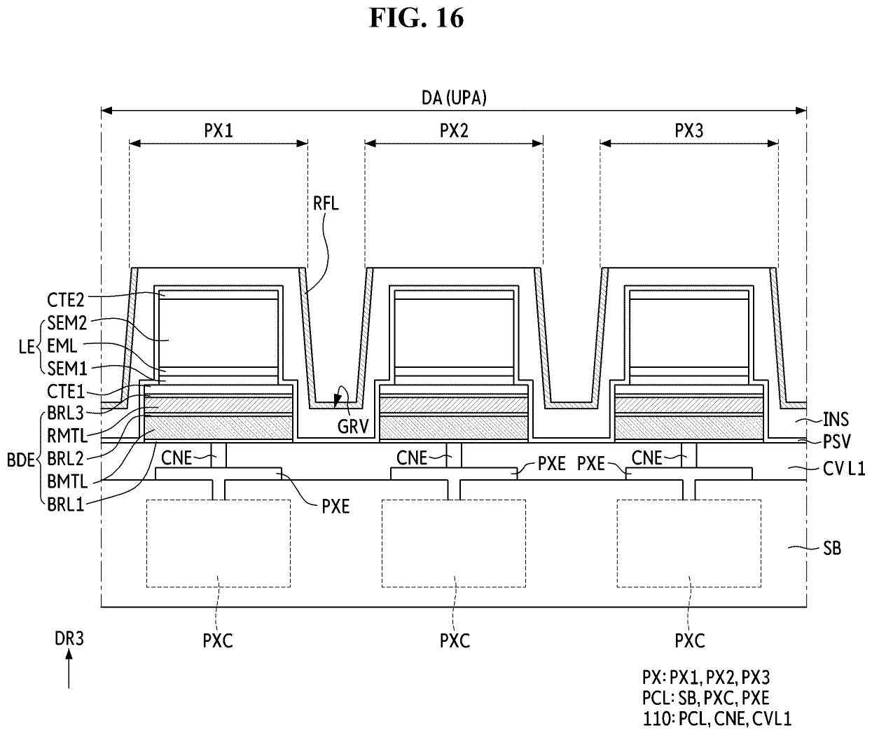

Referring to FIG. 16, the reflective film RFL may be formed on the groove GRV of the insulating layer INS. Accordingly, the reflective film RFL having a shape corresponding to the shape of the groove GRV may be formed at positions where the groove GRV is disposed. The reflective film RFL may surround the side surfaces of the light emitting elements LE. For example, the reflective film RFL may have a mesh shape surrounding the light emitting elements LE in plan view and may face the side surfaces of the light emitting elements LE in cross section.

The reflective film RFL disposed on the groove GRV of the insulating layer INS as well as the reflective layer RMTL of each of the bonding electrodes BDE may appropriately reflect light that travels in downward and lateral directions of the light emitting elements LE, thereby increasing the amount of light emitted in an upward direction of each of the light emitting elements LE. Accordingly, the light efficiency of the light emitting elements LE and the pixels PX including the light emitting elements LE can be improved.

In an embodiment, in case that a reflective film RFL including a textured pattern TXP as in the embodiment of FIG. 4 is to be formed, an additional process may be performed to form the textured pattern TXP on a surface of the reflective film RFL. For example, after the reflective film RFL is formed, the textured pattern TXP may be formed on a surface of the reflective film RFL through annealing or the like to give surface roughness. Accordingly, the light reflectance of the reflective film RFL can be further increased.

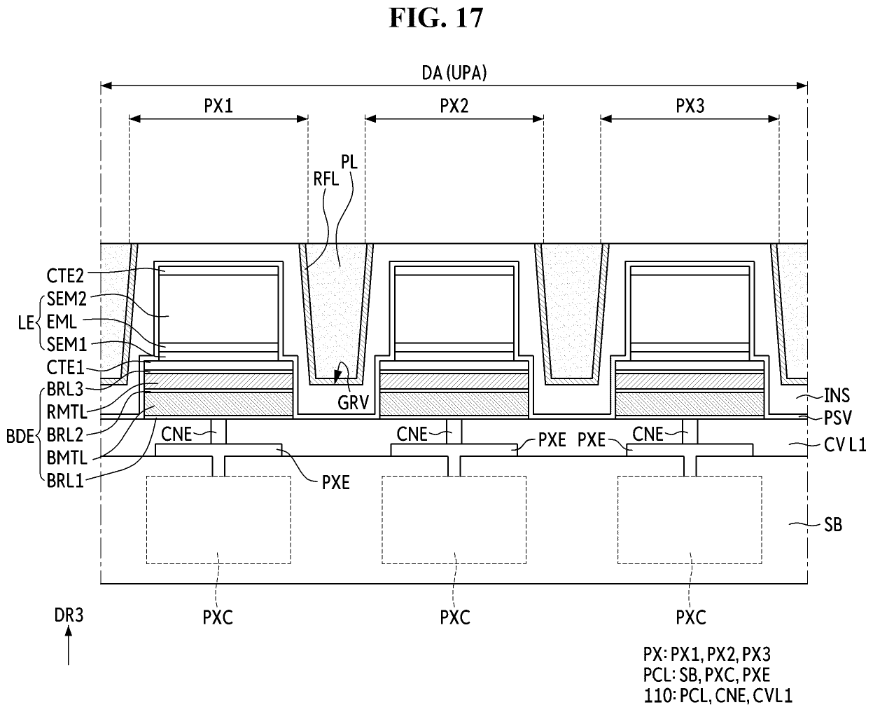

Referring to FIG. 17, the power line PL may be formed on the reflective film RFL. In an embodiment, a conductive film may be formed to a height greater than or equal to those of the insulating layer INS and the reflective film RFL to completely fill the groove GRV on which the reflective film RFL is formed. An etching process or a planarization process such as a polishing process (for example, a CMP process) may be performed to form the power line PL of a mesh shape including openings that expose the light emitting elements LE. Accordingly, the power line PL having a shape corresponding to the shape of the groove GRV may be formed at the positions where the groove GRV is disposed. For example, the power line PL may have a mesh shape surrounding the light emitting elements LE in plan view. The formation method or shape of the power line PL is not limited to the above-described embodiment and may vary according to embodiments.

Referring to FIG. 18, the passivation layer PSV and the insulating layer INS on each of the light emitting elements LE may be etched to form an opening OPN that exposes a portion of each of the second contact electrodes CTE2 (or the light emitting elements LE). In an embodiment, the passivation layer PSV and the insulating layer INS may include materials having different etch selectivities and may include openings of different sizes.

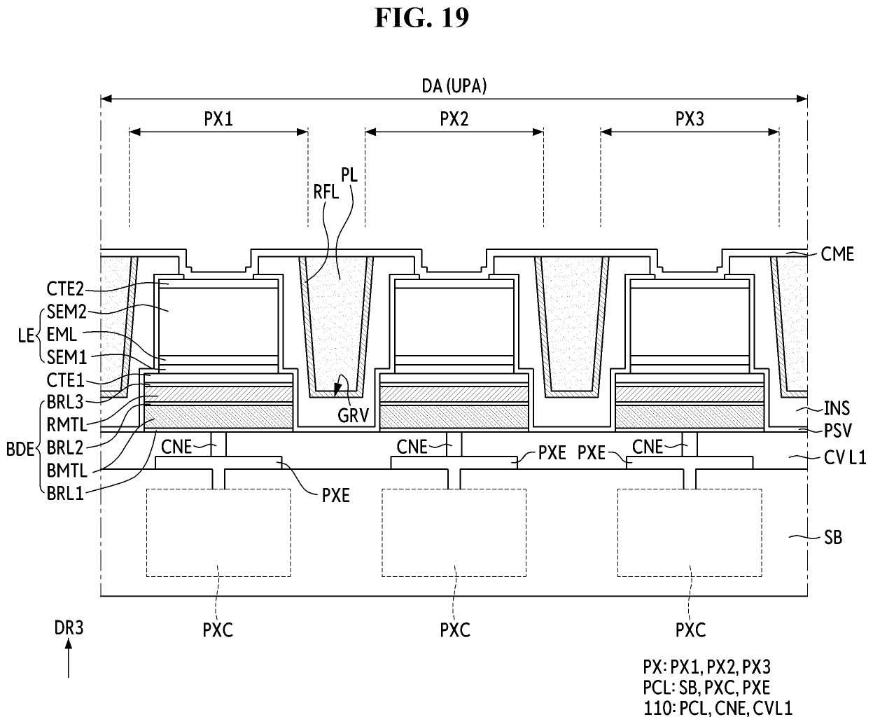

Referring to FIG. 19, the common electrode CME may be formed on the light emitting elements LE, the insulating layer INS, the reflective film RFL, and the power line PL. The common electrode CME may be formed (e.g., entirely formed) on the light emitting elements LE using a material described above. For example, the common electrode CME may be formed in the entire display area DA.

The common electrode CME may also be disposed or formed in the openings OPN of FIG. 18. Accordingly, the common electrode CME and the light emitting elements LE may be electrically connected to each other. For example, the common electrode CME may be electrically connected to the light emitting elements LE by contacting the second contact electrode CTE2 (or the light emitting element LE) in each opening OPN.

In an embodiment, the common electrode CME may be disposed or formed on (e.g., directly on) the power line PL. Accordingly, the common electrode CME and the power line PL may be electrically connected to each other.

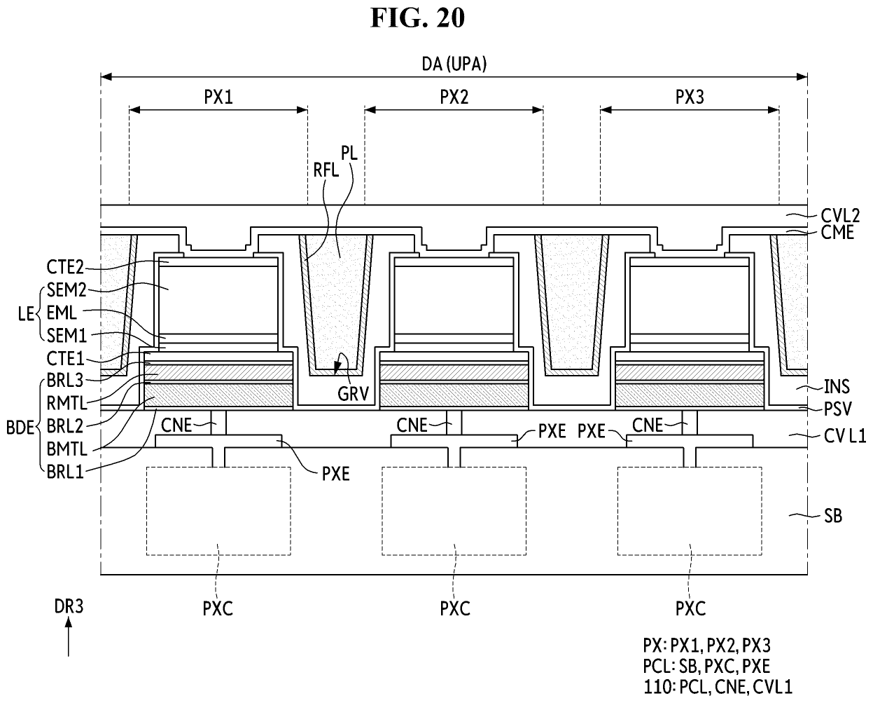

Referring to FIG. 20, a second cover layer CVL2 may be formed on the common electrode CME. The second cover layer CVL2 may be formed using a material suitable for protecting the light emitting elements LE and the pixels PX including the light emitting elements LE. For example, the second cover layer CVL2 may be formed on the entire surface of the common electrode CME using an inorganic insulating material or an organic insulating material described above.

In an embodiment, in case that a display panel DPN may include an additional element disposed on the second cover layer CVL2, a process of forming or placing the element may be performed. For example, in case that a display panel DPN (or a display device 10) including lenses LS as illustrated in FIGS. 3 and 4 is manufactured, the lenses LS may be formed or placed on the second cover layer CVL2. The lenses LS may be formed integral with the display panel DPN or may be formed separately from the display panel DPN and placed on the display panel DPN.

Through the above-described process, the display panel DPN according to the embodiment of FIG. 3 may be manufactured. The display panel DPN according to the embodiment of FIG. 4 may be manufactured by forming the textured pattern TXP on a surface of the reflective film RFL in case that the reflective film RFL is formed or immediately after the reflective film RFL is formed.

As described above, the display device 10 according to the embodiments may include the reflective film RFL disposed on the groove GRV of the insulating layer INS and surrounding the side surfaces of the light emitting elements LE. According to the display device 10 and the method of manufacturing the same according to the embodiments, the light efficiency of the light emitting elements LE and the pixels PX including the light emitting elements LE can be increased. Light leakage or light interference between the pixels PX can be prevented, and the electrical stability of the light emitting elements LE and the reflective film RFL can be secured.

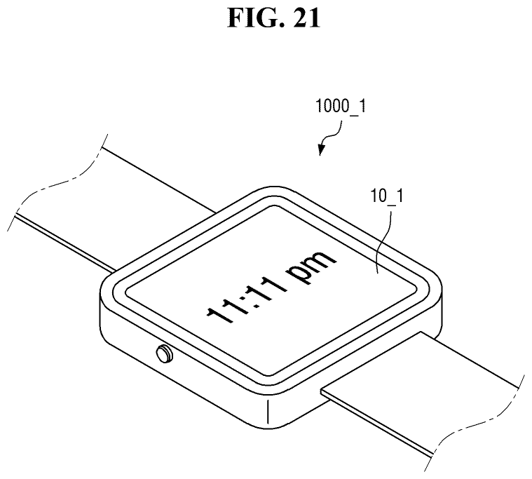

FIG. 21 is an example view of a smart watch 1000_1 including a display device 10_1 according to an embodiment.

Referring to FIG. 21, the display device 10_1 according to the embodiment may be applied to the smart watch 1000_1 which is one of smart devices.

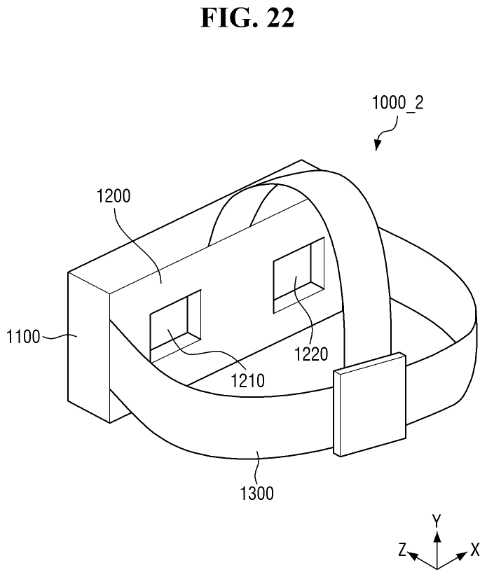

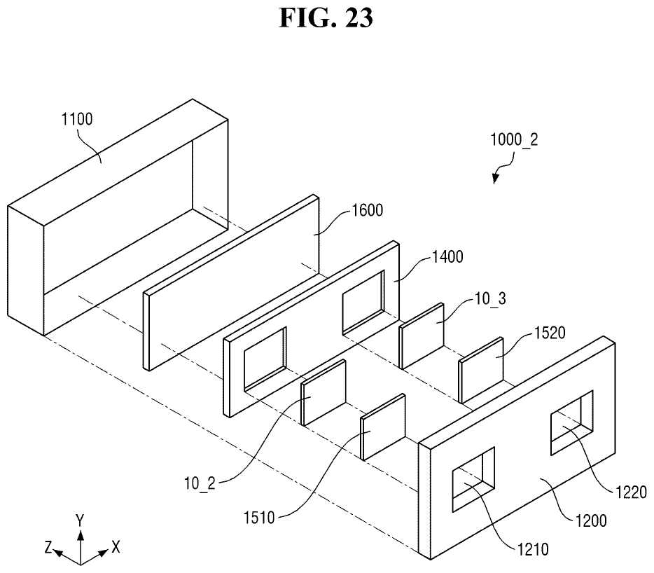

FIGS. 22 and 23 are example views of a virtual reality (VR) device including display devices according to an embodiment.

Referring to FIGS. 22 and 23, the VR device according to the embodiment may be a head mounted display device 1000_2. The head mounted display device 1000_2 may include a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 10_3 provides an image to the user's right eye.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and may be disposed between the second display device 10_3 and the control circuit board 1600. The middle frame 1400 supports and fixes the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source received from the outside into video data and transmit the video data to the first display device 10_2 and the second display device 10_3 through the connector.

The control circuit board 1600 may transmit video data corresponding to a left image optimized for a user's left eye to the first display device 10_2 and transmit video data corresponding to a right image optimized for the user's right eye to the second display device 10_3. By way of example, the control circuit board 1600 may transmit the same video data to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 22 and 23, embodiments of the specification are not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

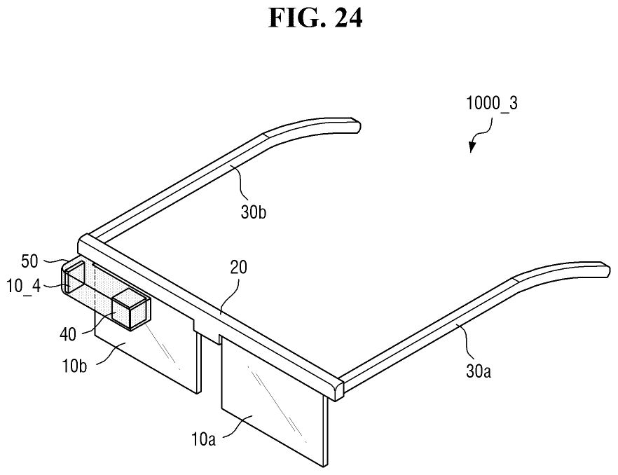

The head mounted band 1300 fixes the display device housing 1100 to a user's head so that the first eyepiece 1210 and the second eyepiece 1220 of the housing cover 1200 are kept placed on the user's left and right eyes, respectively. In case that the display device housing 1100 is implemented to be lightweight and small, the head mounted display device 1000_2 may include an eyeglass frame as illustrated in FIG. 24 instead of the head mounted band 1300.

The head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 24 is an example view of a virtual reality (VR) device 1000_3 including a display device 10_4 according to an embodiment.

Referring to FIG. 24, the VR device 1000_3 (or AR device) according to the embodiment may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 24, a case where the VR device 1000_3 is a glasses-type display device including the eyeglass frame legs 30a and 30b is illustrated as an example. However, embodiments are not limited thereto. For example, the VR device 1000_3 can be applied in various forms to various other electronic devices.

The display device housing 50 may include the display device 10_4 and the reflective member 40 (or a light path conversion member). An image displayed on the display device 10_4 may be reflected by the reflective member 40 and provided to a user's right eye through the right lens 10b. Accordingly, the user may view a VR image displayed on the display device 10_4 through the right eye. For example, the user may view an AR image, into which a virtual image displayed on the display device 10_4 and a real image viewed through the right lens 10b are combined, through the right eye.

Although the display device housing 50 is disposed at a right end of the support frame 20 in FIG. 24, embodiments of the specification are not limited thereto. For example, the display device housing 50 may also be disposed at a left end of the support frame 20. An image displayed on the display device 10_4 may be reflected by the reflective member 40 and provided to the user's left eye through the left lens 10a. Accordingly, the user may view a VR image displayed on the display device 10_4 through the left eye. By way of example, the display device housing 50 may be disposed at both the right end and the left end of the support frame 20. The user may view a VR image displayed on the display device 10_4 through both the left eye and the right eye.

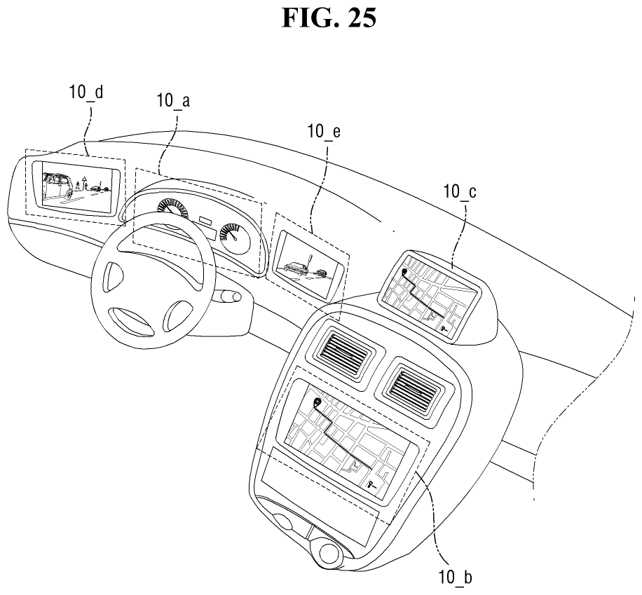

FIG. 25 is an example view illustrating a vehicle instrument cluster and center fascia including display devices according to an embodiment. FIG. 25 illustrates a vehicle to which display devices 10_a through 10_e according to an embodiment have been applied.

Referring to FIG. 25, the display devices 10_a through 10_c according to the embodiment may be applied to an instrument cluster of the vehicle, a center fascia of the vehicle, or a center information display (CID) disposed on a dashboard of the vehicle. The display devices 10_d and 10_e according to the embodiment may be applied to room mirror displays that replace side mirrors of the vehicle.

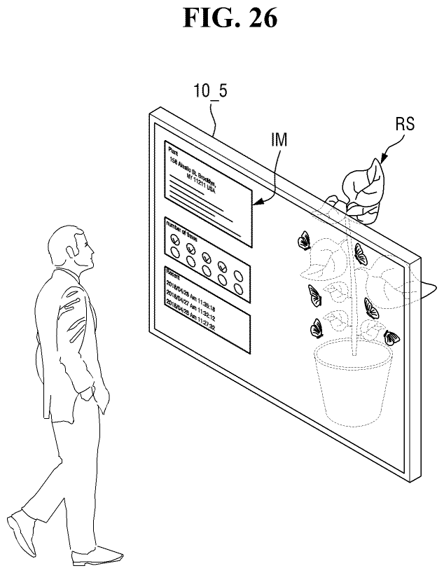

FIG. 26 is an example view of a transparent display device including a display device 10_5 according to an embodiment.

Referring to FIG. 26, the display device 10_5 according to the embodiment may be applied to the transparent display device. The transparent display device may transmit light while displaying an image IM. Therefore, a user located in front of the transparent display device cannot only view the image IM displayed on the display device 10_5 but also view an object RS or the background located behind the transparent display device. In case that the display device 10_5 is applied to the transparent display device, a substrate of the display device 10_5 may include a light transmitting portion that can transmit light or may be made of a material that can transmit light.

At least one of the display devices 10_1, 10_2, 10_3, 10_4, 10_5, 10_a, 10_b, 10_c, 10_d, and 10_e according to the embodiments of FIGS. 21 through 26 may be a display device (for example, the display device 10 of FIG. 1) to which at least one of the embodiments described above is applied. For example, at least one of the display devices 10_1, 10_2, 10_3, 10_4, 10_5, 10_a, 10_b, 10_c, 10_d, and 10_e according to the embodiments of FIGS. 21 through 26 may include a reflective film RFL disposed on a groove GRV of an insulating layer INS and surrounding side surfaces of light emitting elements LE.

In concluding the detailed description, those skilled in the art will appreciate that many variations and modifications can be made to the embodiments without substantially departing from the principles of the disclosure. Therefore, the disclosed embodiments are used in a generic and descriptive sense only and not for purposes of limitation.

What is claimed is:

1. A display device comprising:
a lower substrate;
light emitting elements disposed on the lower substrate;
a passivation layer covering side surfaces of the light emitting elements;
an insulating layer disposed on the passivation layer and comprising a groove surrounding the light emitting elements; and
a reflective film disposed on the groove and surrounding the side surfaces of the light emitting elements.

2. The display device of claim 1, wherein the reflective film has a mesh shape comprising openings exposing the light emitting elements in plan view.

3. The display device of claim 1, wherein the reflective film comprises a surface having a textured pattern and has a surface roughness according to the textured pattern.

4. The display device of claim 1, wherein
a depth of the groove is equal or greater than a thickness of the light emitting elements, and
a bottom surface of the reflective film is disposed at a same height as or below the light emitting elements.

5. The display device of claim 1, wherein the reflective film comprises a metal or distributed Bragg reflectors.

6. The display device of claim 1, further comprising:
bonding electrodes disposed on the lower substrate,
wherein the light emitting elements are disposed on the bonding electrodes.

7. The display device of claim 6, wherein each of the bonding electrodes comprises a bonding layer and a reflective layer disposed on the bonding layer.

8. The display device of claim 7, wherein the reflective layer of each of the bonding electrodes completely covers a lower surface of each of the light emitting elements.

9. The display device of claim 1, further comprising:
a common electrode disposed on the insulating layer and electrically connected to the light emitting elements.

10. The display device of claim 9, further comprising:
a power line disposed on the reflective film and filling the groove,
wherein the common electrode is disposed on the power line.

11. The display device of claim 9, further comprising:
a cover layer disposed on the common electrode; and
lenses disposed on the cover layer and overlapping the light emitting elements.

12. A method of manufacturing a display device, the method comprising:
preparing a lower substrate comprising pixel circuits;
forming light emitting elements, electrically connected to the pixel circuits, on the lower substrate;
forming a passivation layer, covering the light emitting elements, on the lower substrate;
forming an insulating layer, comprising a groove surrounding the light emitting elements, on the passivation layer;
forming a reflective film, surrounding side surfaces of the light emitting elements, on the groove; and
forming a common electrode, electrically connected to the light emitting elements, on the insulating layer.

13. The method of claim 12, wherein the forming of the insulating layer comprises:
forming the insulating layer on the passivation layer to a height greater than a height of the light emitting elements such that the insulating layer completely covers the light emitting elements; and
forming the groove in the insulating layer by etching the insulating layer in a portion not overlapping the light emitting elements.

14. The method of claim 12, further comprising:
forming a textured pattern on a surface of the reflective film after the reflective film is formed.

15. An electronic device for providing an image, the electronic device comprising:
a display device comprising:
a lower substrate;
light emitting elements disposed on the lower substrate;
a passivation layer covering side surfaces of the light emitting elements;
an insulating layer disposed on the passivation layer and comprising a groove surrounding the light emitting elements; and
a reflective film disposed on the groove and surrounding the side surfaces of the light emitting elements.

16. The electronic device of claim 15, wherein the reflective film has a mesh shape comprising openings exposing the light emitting elements in plan view.

17. The electronic device of claim 16, wherein the reflective film and the light emitting elements do not overlap each other in plan view.

18. The electronic device of claim 15, wherein the reflective film comprises a surface having a textured pattern and has a surface roughness according to the textured pattern.

19. The electronic device of claim 15, wherein a depth of the groove is equal or greater than a thickness of the light emitting elements, and a bottom surface of the reflective film is disposed at a same height as or below the light emitting elements.

20. The electronic device of claim 19, wherein the reflective film completely surrounds the side surfaces of each of the light emitting elements.
